(19) United States
(12) Patent Application Publication
(10) Pub. No.: US 2013/0234128 A1
(43) Pub. Date: Sep. 12, 2013

(54) ORGANIC SEMICONDUCTOR DEVICE

(71) Applicant: Shigeru Aomori, Osaka-shi (JP)

(72) Inventor: Shigeru Aomori, Osaka-shi (JP)

(21) Appl. No.: 13/885,680

(22) PCT Filed: Nov. 17, 2011
(86) PCT No.: PCT/JP2011/076518

§ 371 Date: May 15, 2013

(30) Foreign Application Priority Data
Nov. 19, 2010 (JP) 2010-259221

(51) Int. Cl. H01L 27/32

(52) U.S. Cl. CPC H01L 27/32
USPC 257/40

(57) ABSTRACT

An object of the present invention is to facilitate reduction in channel length and increase in channel width in an organic semiconductor device and to improve yield. According to an embodiment of the present invention, an organic semiconductor device includes a laminate provided in a first region of a substrate and including a first electrode, a first organic semiconductor film, and a second electrode which are laminated with each other, the first organic semiconductor film being placed between the first electrode and the second electrode; a first wiring portion provided in a second region adjacent to a portion of the periphery of the first region so as to be electrically connected to the first electrode; a second wiring portion provided in the second region so as to be electrically connected to the second electrode; a gate electrode which surrounds a portion of the periphery of the first region; and a gate insulating film provided at least between the laminate and the gate electrode.

### TECHNICAL FIELD

The present invention relates to a semiconductor device using an organic semiconductor material. In detail, the present invention relates to a thin-film transistor including an organic semiconductor film, an organic semiconductor device including combination of a plurality of thin-film transistors, an organic semiconductor device array including an array of organic thin-film transistors, a liquid crystal display device, and an organic electroluminescence display device.

This application claims priority based on Japanese Patent Application No. 2010-259221 filed Nov. 19, 2010, the contents of which are incorporated herein by reference.

### BACKGROUND ART

There have been known thin-film transistors composed of inorganic semiconductor materials, such as silicon-based materials, for example, amorphous silicon and polysilicon, and the like. On the other hand, organic thin-film transistors using organic semiconductor materials have recently attracted attention. Organic thin-film transistors can be generally manufactured even by a simple manufacturing method, for example, a printing method, and reduction in manufacturing cost and manufacture of large-area devices can be easily attempted. Organic semiconductor devices including such organic thin-film transistors are expected to be applied to so-called flexible electronics devices in each of which elements and integrated circuits are formed on a flexible substrate. Examples of the flexible electronics devices include a flexible display, a solar cell, a radio frequency identification (RFID) tags, and the like.

The organic thin-film transistors are roughly classified into low-molecular organic thin-film transistors and high-molecular organic thin-film transistors according to the main organic semiconductor materials used. The low-molecular organic thin-film transistors are mainly manufactured by a vacuum deposition method. The high-molecular organic thin-film transistors are mainly manufactured by a printing method.

In a thin-film transistor, a drain current Id flowing between source and drain electrodes can be generally represented by formula (1) below. In the formula (1), Cₒₓ represents gate capacitance [F/m³], μ represents electron field-effect mobility [cm²/Vs], V_{g} represents a gate voltage [V], Vₜₕ represents a threshold voltage [V], L represents a channel length [μm], and W represents a channel width [μm].

$$\begin{matrix}[ Formula 1 ] & \\ Id = \frac{W \cdot Cox}{2 \cdot L} {μ ( Vg - Vth )}^{2} & ( 1 )\end{matrix}$$

The electron field-effect mobility μ is a parameter depending on a semiconductor material. The electron field-effect mobility of inorganic thin-film transistors is about 0.3 [cm²/Vs] to several hundreds [cm²/Vs]. The electron field-effect mobility of organic thin-film transistors is reported to be in a wide range of 10⁻³ [cm²/Vs] to 1.0 [cm²/Vs] or more. Therefore, organic thin-film transistors generally have lower electron field-effect mobility than that of inorganic thin-film transistors and are thus expected to be improved in performance for realizing the flexible electronics devices and the like. In view of an attempt to improve performance of organic thin-film transistors, improvement in characteristics by design of element structures is investigated in combination with improvement in characteristics by development of organic semiconductor materials. In order to increase a drain current by designing an element structure, as seen from the formula (1), it is effective to decrease the channel length L and increase the channel width W.

A structure known as a general thin-film transistor structure is a so-called planar-type structure. The planar-type structure includes a semiconductor film held between source and drain electrodes in a direction parallel to a substrate surface, a gate insulating film laminated on the semiconductor film in a direction perpendicular to the substrate surface, and a gate electrode which applies an electric field to the semiconductor film through the gate insulating film. The channel length L in the planar-type structure is restricted by the pattern precision of a manufacturing process, process resistance of organic semiconductors, etc. In these situations, the channel length L in the planar-type structure is generally set to several μm to several tens μm and cannot be easily greatly reduced. In addition, in the planar-type structure, a planar element size increases as the channel width W increases, and thus the channel width W cannot be easily increased while the size of an element is decreased.

In contrast to the planar-type structure, a vertical-type structure in which a channel length L can be easily reduced is proposed in, for example, Patent Literatures 1 to 3 etc. The vertical-type structure includes a laminate in which a source electrode, a semiconductor film, and a drain electrode are laminated in a direction perpendicular to a substrate surface, a gate electrode provided at a distance from the laminate in a direction parallel to the substrate surface, and a gate insulating film sandwiched between the laminate and the gate electrode. The vertical-type structure has a channel length L equivalent to the thickness of the semiconductor film, and thus the channel length L can be more easily reduced than in the planar-type structure.

Patent Literature 3 employs a structure in which a gate electrode is disposed to circularly surround the periphery of a laminate including a source electrode, a semiconductor film, and a drain electrode which are laminated with each other. In the structure of Patent Literature 3, the peripheral length of the laminate corresponds to the channel width W, and thus the channel width W can be more easily increased than in the planar-type structure.

### CITATION LIST

### Patent Literature

PTL 1: Japanese Unexamined Patent Application Publication No. 2003-110110
PTL 2: Japanese Unexamined Patent Application Publication No. 2003-31816
PTL 3: Japanese Unexamined Patent Application Publication No. 2005-167164

### SUMMARY OF INVENTION

### Technical Problem

The vertical-type structure has the following problems. Patent Literatures 1 to 3 disclose a structure in which a source electrode and a drain electrode face each other with an organic semiconductor film disposed therebetween. Therefore, a parasitic capacitance corresponding to the area of the overlapping electrodes increases as the thickness of the organic semiconductor film decreases. Also, in Patent Literatures 1 to 3, as the thickness of the organic semiconductor film decreases, a so-called leakage current or the like flowing between the source electrode and the drain electrode more easily occurs regardless of control of the gate voltage. An increase in the parasitic capacitance and an increase in the leakage current may interfere with application of an organic thin-film transistor to a device or the like.

Although the channel width W in the structure of Patent Literature 3 can be easily increased, the yield or the like is likely to be decreased as described below. Patent Literature 3 requires a structure in which wiring is drawn to the outside of the gate electrode because the gate electrode surrounds the periphery of the laminate. That is, one of the wiring from the laminate and the gate electrode crosses over the other, thereby easily causing a failure of disconnection of the electrode or wiring by step difference of an underlying base.

The present invention has been achieved in consideration of the above-mentioned situations, and an object of the present invention is to make it easy to shorten the channel length and increase the channel width in an organic thin-film transistor and to improve the yield of the organic thin-film transistor.

### Solution to Problem

According to a first embodiment of the present invention, an organic semiconductor device includes a laminate provided in a predetermined region of a substrate and including a first electrode, an organic semiconductor film, and a second electrode which are laminated with each other so that the organic semiconductor film is placed between the first electrode and the second electrode, a first wiring portion provided in a region adjacent to a portion of the periphery of the predetermined region so as to be electrically connected to the first electrode, a second wiring portion provided in the adjacent region so as to be electrically connected to the second electrode, a gate electrode extending to be bent along the periphery of the predetermined region excluding the adjacent region, and a gate insulating film provided between at least the laminate and the gate electrode.

In the organic semiconductor device according to the first embodiment, the area of the first electrode may be different from the area of the second electrode.

In the organic semiconductor device according to the first embodiment, the area of a portion of the first electrode which overlaps the organic semiconductor film in the lamination direction of the laminate may be different from the area of a portion of the second electrode which overlaps the organic semiconductor film in the lamination direction of the laminate.

In the organic semiconductor device according to the first embodiment, the organic semiconductor film may be made of an n-type semiconductor material or a p-type semiconductor material.

The organic semiconductor device according to the first embodiment may include the organic semiconductor film partially formed as a first organic semiconductor film on the first electrode, the second electrode formed on the first organic semiconductor film, a second organic semiconductor film provided on the first electrode within a region different from the first organic semiconductor film, a third electrode provided on the second organic semiconductor film, and a third wiring portion provided in the adjacent region so as to be electrically connected to the third electrode, wherein one of the first organic semiconductor film and the second organic semiconductor film may be made of an n-type semiconductor material, and the other may be made of a p-type semiconductor material.

In the organic semiconductor device according to the first embodiment, the organic semiconductor film contains a plurality of organic molecules which are chemically bonded to each other in association with molecular axis alignment due to development of π-conjugation in a direction from one of a pair of the electrodes laminated with the organic semiconductor film to the other.

In the organic semiconductor device according to the first embodiment, the predetermined region has a substantially rectangular shape, and the gate electrode may be provided to surround three sides of the predetermined region without surrounding at least a portion of one side except the three sides of the predetermined region.

According to a second embodiment of the present invention, an organic semiconductor device array includes an array of a plurality of organic semiconductor devices according to the first embodiment.

According to a third embodiment of the present invention, a liquid crystal display device includes at least one of the organic semiconductor device according to the first embodiment and the organic semiconductor device array according to the second embodiment.

According to a fourth embodiment of the present invention, an organic electroluminescence display device includes at least one of the organic semiconductor device according to the first embodiment and the organic semiconductor device array according to the second embodiment.

### Advantageous Effects of Invention

According to the present invention, it is possible to easily shorten the channel length and increase the channel width in an organic thin-film transistor and to improve the yield of the organic thin-film transistor.

### BRIEF DESCRIPTION OF DRAWINGS

FIG. 1 is a plan view of an organic semiconductor device according to a first embodiment.

FIG. 2 is a cross-sectional view take along line A-A′ in FIG. 1.

FIG. 3 is a cross-sectional view take along line B-B′ in FIG. 1.

FIG. 4 is a cross-sectional view take along line C-C′ in FIG. 1.

FIG. 5 is a plan view and cross sectional view showing manufacturing steps of a method for manufacturing the organic semiconductor device according to the first embodiment.

FIG. 6 is a plan view and cross sectional view showing manufacturing steps subsequent to FIG. 5.

FIG. 7 is a plan view and cross sectional view showing manufacturing steps subsequent to FIG. 6.

FIG. 8 is a plan view and cross sectional view showing manufacturing steps subsequent to FIG. 7.

FIG. 9 is a plan view and cross sectional view showing manufacturing steps subsequent to FIG. 8.

FIG. 10 is a cross-sectional view of an organic semiconductor device according to modified example 1.

FIG. 11 is a plan view of an organic semiconductor device according to modified example 2.

FIG. 12 is a cross-sectional view take along line D-D′ in FIG. 11.

FIG. 13 is a plan view of an organic semiconductor device according to modified example 3.

FIG. 14 is a cross-sectional view take along line E-E′ in FIG. 13.

FIG. 15 is a plan view of an organic semiconductor device according to a second embodiment.

FIG. 16 is a cross-sectional view take along line F-F′ in FIG. 15.

FIG. 17 is an explanatory view illustrating an example of π-conjugated organic molecules.

FIG. 18A is a cross-sectional view showing manufacturing steps of a method for manufacturing the organic semiconductor device according to the second embodiment.

FIG. 18B is a cross-sectional view showing manufacturing steps subsequent to FIG. 18A.

FIG. 18C is a cross-sectional view showing manufacturing steps subsequent to FIG. 18B.

FIG. 18D is a cross-sectional view showing manufacturing steps subsequent to FIG. 18C.

FIG. 19 is a plan view of an organic semiconductor device according to a third embodiment.

FIG. 20 is a cross-sectional view take along line G-G′ in FIG. 19.

FIG. 21 is an equivalent circuit diagram of the organic semiconductor device according to the third embodiment.

FIG. 22 is a plan view and cross-sectional view showing manufacturing steps of a method for manufacturing the organic semiconductor device according to the third embodiment.

FIG. 23 is a plan view and cross-sectional view subsequent to FIG. 22.

FIG. 24 is a plan view and cross-sectional view subsequent to FIG. 23.

FIG. 25 is a plan view and cross-sectional view subsequent to FIG. 24.

FIG. 26 is a plan view and cross-sectional view subsequent to FIG. 25.

FIG. 27 is a plan view of an organic semiconductor device according to modified example 4.

FIG. 28 is a cross-sectional view take along line H-H′ in FIG. 27.

FIG. 29 is a plan view of an organic semiconductor device array according to a fourth embodiment.

FIG. 30 is a plan view of an organic semiconductor device according to the fourth embodiment.

FIG. 31 is a cross-sectional view take along line J-J′ in FIG. 30.

FIG. 32 is a cross-sectional view take along line K-K′ in FIG. 30.

FIG. 33A is a plan view of a constituent element of the organic semiconductor device according to the fourth embodiment.

FIG. 33B is a plan view of a constituent element of the organic semiconductor device according to the fourth embodiment.

FIG. 33C is a plan view of a constituent element of the organic semiconductor device according to the fourth embodiment.

FIG. 34 is a plan view of an organic semiconductor device in an organic semiconductor device array of a liquid crystal display device according to a fifth embodiment.

FIG. 35 is a cross-sectional view take along line L-L′ in FIG. 34.

FIG. 36 is a cross-sectional view take along line M-M′ in FIG. 34.

FIG. 37 is a plan view of an organic semiconductor device in an organic semiconductor device array of an organic electroluminescence display device according to a sixth embodiment.

FIG. 38 is an equivalent circuit diagram of the organic semiconductor device according to the sixth embodiment.

FIG. 39A is a plan view of a constituent element of the organic semiconductor device according to the sixth embodiment.

FIG. 39B is a plan view of a constituent element of the organic semiconductor device according to the sixth embodiment.

FIG. 39C is a plan view of a constituent element of the organic semiconductor device according to the sixth embodiment.

FIG. 39D is a plan view of a constituent element of the organic semiconductor device according to the sixth embodiment.

FIG. 39E is a plan view of a constituent element of the organic semiconductor device according to the sixth embodiment.

FIG. 39F is a plan view of a constituent element of the organic semiconductor device according to the sixth embodiment.

### DESCRIPTION OF EMBODIMENTS

Although embodiments of the present invention are described below with reference to the drawings, the present invention is not limited to these embodiments. In the embodiments and modified examples described below, the same constituent element is denoted by the same reference numeral, and duplicated description may be omitted. Requirements described in the embodiments or modified examples below can be appropriately combined.

### First Embodiment

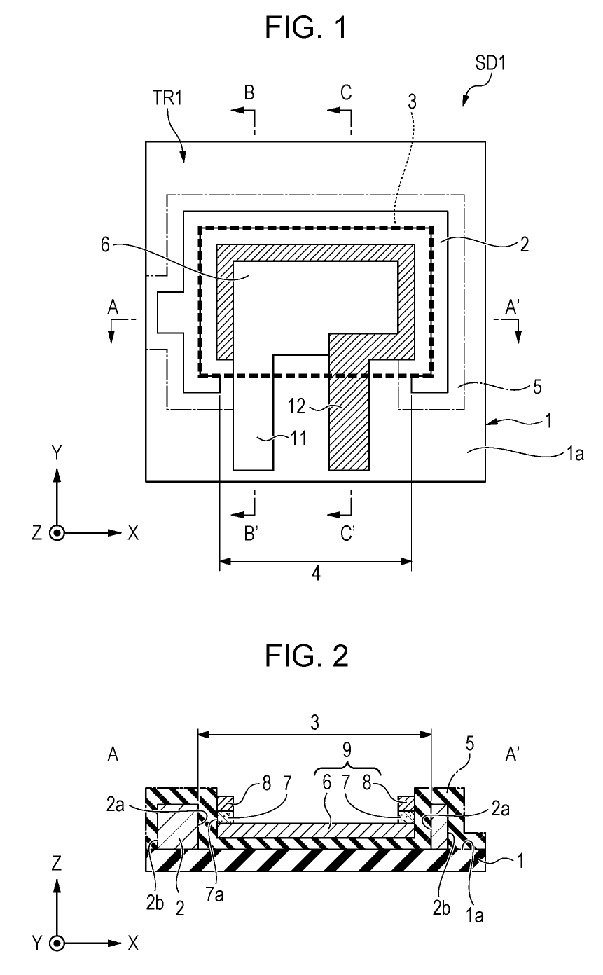

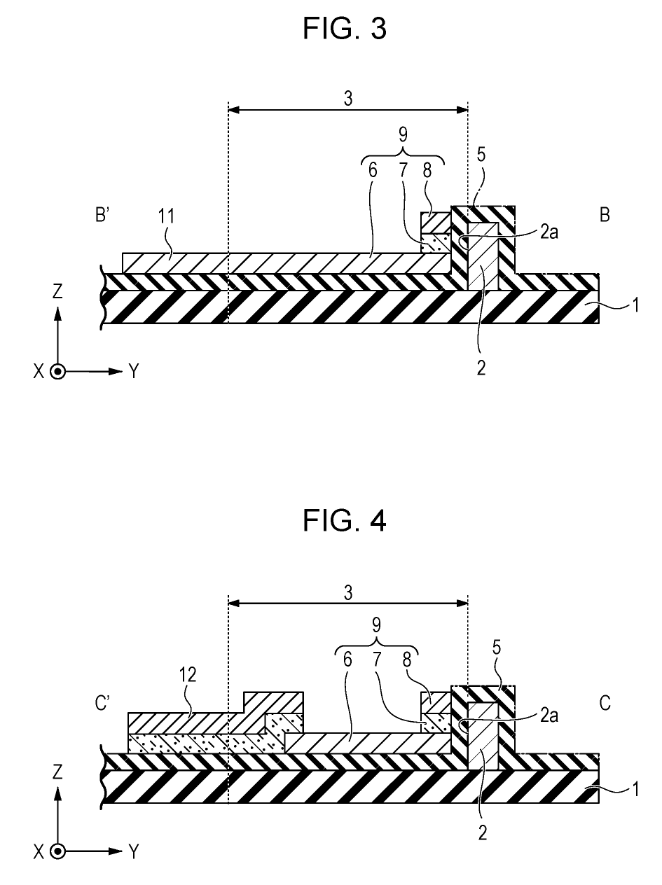

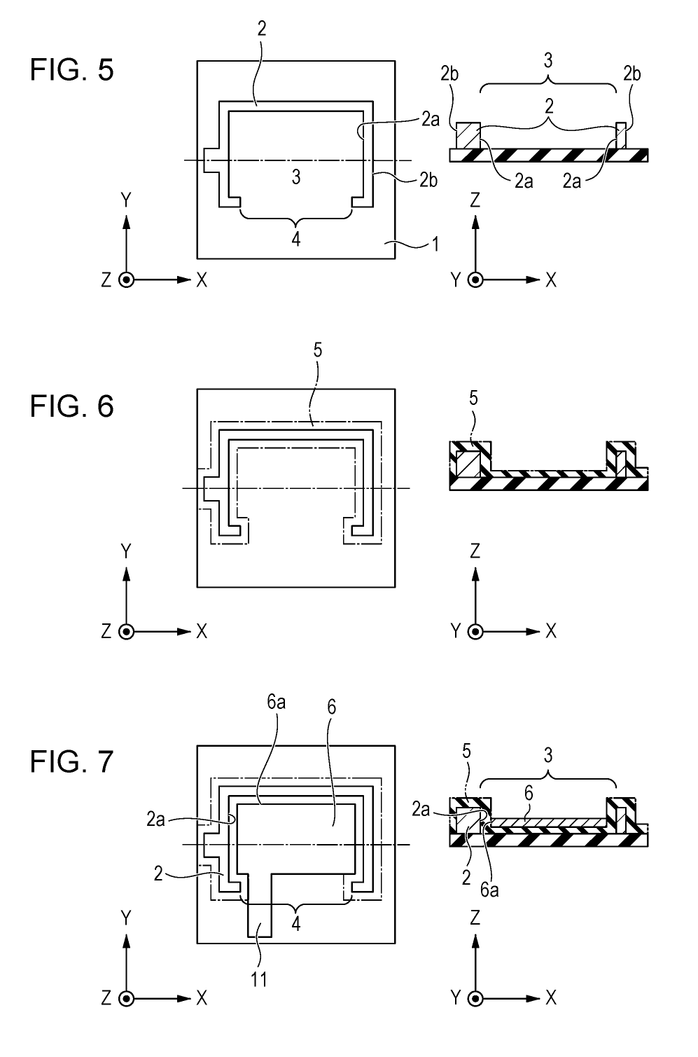

A first embodiment is described. FIG. 1 is a plan view of an organic semiconductor device according to the first embodiment. FIG. 2 is a cross-sectional view take along line A-A′ in FIG. 1. FIG. 3 is a cross-sectional view take along line B-B′ in FIG. 1. FIG. 4 is a cross-sectional view take along line C-C′ in FIG. 1. FIGS. 5 to 9 are process views showing an example a method for manufacturing the organic semiconductor device according to the first embodiment. FIGS. 5 to 9 each show a process plan view (view on the left) and a process cross-sectional view (view on the right) taken along a one-dot chain line in the process plan view.

An organic semiconductor device SD1 according to the first embodiment includes a substrate (hereinafter referred to as an “insulating substrate 1”), a vertical-type structure organic thin-film transistor TR1, a first wiring portion 11, and a second wiring portion 12. The organic thin-film transistor TR1, the first wiring portion 11, and the second wiring portion 12 are formed on a substrate surface 1a of the insulating substrate 1. The first wiring portion 11 and the second wiring portion 12 are electrically connected to the organic thin-film transistor TR1.

The insulating substrate 1 has insulation properties at least on the substrate surface 1a thereof. The insulating substrate 1 is a substrate made of an insulating material, for example, a glass substrate, a resin substrate, or the like. The insulating substrate 1 may be a substrate which is composed of a conductive material such as aluminum, stainless steel, or the like, or a semiconductor material such as silicon, and which has an insulating film formed on at least one of the sides. The insulating substrate 1 may be a plate-shaped member or a foil-shaped member. The insulating substrate 1 may be a substrate having flexibility.

The organic thin-film transistor TR1 includes a gate electrode 2, a laminate 9, and a gate insulating film 5. The laminate 9 has a first electrode 6, an organic semiconductor film 7, and a second electrode 8 which are laminated in a direction normal to the substrate surface 1a.

The gate electrode 2 is disposed outside a predetermined region 3 (first region) of the substrate surface 1a and adjacent to the outer periphery of the predetermined region 3. The laminate 9 is disposed inside the predetermined region 3 at a distance, which corresponds to the thickness of the gate insulating film 5, from the gate electrode 2 surrounding the outer periphery of the predetermined region 3. The gate insulating film 5 is provided at least between the inner peripheral surface 2a of the gate electrode 2 and the laminate 9 in a direction parallel to the substrate surface 1a.

In this embodiment, the predetermined region 3 is the region surrounded by the gate electrode 2. In this embodiment, the shape of the predetermined region 3 is a substantially rectangular shape. The substantially rectangular shape is a rectangular shape or a rounded rectangular shape. The shape of the predetermined region 3 may be any one of a polygonal shape, a polygonal shape rounded at the corners thereof, and a shape having a linear or curved contour, such as a circular shape, an elliptical shape, an oval shape, or the like.

The gate electrode 2 is disposed to surround a portion of the outer periphery of the laminate 9. The gate electrode 2 extends to be bent along the outer periphery of the predetermined region 3 in a direction parallel to the substrate surface 1a of the insulating substrate 1. At least a portion of the gate electrode 2 may curvedly extend in a direction parallel to the substrate surface 1a of the insulating substrate 1.

As shown in FIG. 5, the gate electrode 2 according to the embodiment is provided around the predetermined region 3 except in a region (notch portion 4, second region) adjacent to a portion of the outer periphery of the predetermined region 3. The gate electrode 2 according to the embodiment has a shape having the notch portion 4 provided in a portion of a frame in the circumferential direction. Both ends of the gate electrode 2 according to the embodiment face each other with the notch portion 4 disposed therebetween, the notch portion 4 being a region where the gate electrode 2 is not formed. In the embodiment, the region where the gate electrode 2 is formed is a strip-shaped region having a predetermined width in the outward direction from the outer periphery of the predetermined region 3. The gate electrode 2 according to the embodiment has a shape in which the notch portion 4 is provided in one of the sides of a substantially rectangular frame. The notch portion 4 is provided to connect the inner side (predetermined region 3) of the inner peripheral surface 2a of the gate electrode 2 with the outside of the outer peripheral surface 2b of the gate electrode 2.

The gate electrode 2 is composed of a conductive material. Examples of a material which forms the gate electrode 2 include a metallic material, an oxide conductive material, an organic conductive material, a semiconductor material containing a high concentration of impurity, and the like. Examples of the metallic material include elemental metals such as gold, silver, platinum, copper, aluminum, tantalum, titanium, and the like, alloys containing these elemental metals, and the like. Examples of the oxide conductive material include indium tin oxide (ITO), indium gallium zinc oxide (IGZO), zinc oxide, and the like. Examples of the organic conductive material include poly(ethylenedioxythiophene)-polystyrenesulfonate (PEDOT:PSS), and the like. Examples of the semiconductor material containing a high concentration of impurity include polysilicon containing a high concentration of impurity such as phosphorus, boron, or the like.

Examples of a method for forming the gate electrode 2 include first to third methods described below. The first method is a method of forming a conductive film by, for example, a vacuum deposition method, a sputtering method, or the like, and then patterning the conductive film to a desired shape using a photolithography method and an etching method. The second method is a method using a mask deposition method of depositing a formation material through a mask having an aperture with a desired electrode shape. The third method is a method of selectively applying a formation material prepared as a liquid by ink jet printing or screen printing, and then solidifying the liquid formation material. The liquid formation material is, for example, a solution containing the organic conductive material, a dispersion containing fine particles of the metallic material (e.g., silver) dispersed therein, or the like.

The gate insulating film 5 is provided at least between the inner peripheral surface 2a of the gate electrode 2 and the laminate 9 in a direction parallel to the substrate surface 1a. The gate insulating film 5 is placed between the gate electrode 2 and the laminate 9 so as to be in contact with them in a direction parallel to the substrate surface 1a. In the embodiment, the gate insulating film 5 is provided over almost the entire region of the substrate surface 1a so as to cover the gate electrode 2. The laminate 9 is provided on the gate insulating film 5 so as to be disposed inside the predetermined region 3.

The gate insulating film 5 is composed of, for example, an inorganic insulating film or an organic insulating film. Examples of a material which forms the inorganic insulating film include silicon oxide (SiO₂), silicon nitride (SiNₓ), aluminum oxide (Al₂O₃), tantalum oxide (Ta₂O₅), and the like. Examples of a material which forms the organic insulating film include polyimide (PI), polyvinylphenol (PVP), and the like. The gate insulating film 5 may contain a self-assembled monolayer composed of an insulating molecule having an aliphatic hydrocarbon (alkyl chain) with insulation. The capacitance (gate capacitance) of a portion sandwiched between the gate electrode 2 and the laminate 9 increases as the dielectric constant of the gate insulating film 5 increases. The threshold voltage of a vertical organic thin-film transistor can be more decreased with increases in the gate capacitance. A gate insulating film composed of aluminum oxide or tantalum oxide has a higher dielectric constant than that of a gate insulating film composed of one of the above-described other formation materials.

Examples of a method for forming the gate insulating film 5 include a vacuum deposition method, a sputtering method, a printing method, a coating method, a surface modification method, a surface oxidation method, and the like. Examples of the printing method or the coating method include spin coating, ink jet printing, screen printing, insulating film transfer, and the like. The surface modification method is a method of surface-modifying a gate electrode or the like by chemical reaction using insulating organic molecules. The surface oxidation method is a method of oxidizing a surface of the gate electrode 2, for example, made of a metal such as aluminum, tantalum, or the like, by an anodic oxidation method, to form an oxidized portion as the gate insulating film.

In the embodiment, the first electrode 6 is provided on the gate insulating film 5 so as to be in contact with the gate insulating film 5. As shown in FIG. 7, the first electrode 6 according to the embodiment has a substantially rectangular shape. In the embodiment, the outer peripheral surface 6a of the first electrode 6 and the inner peripheral surface 2a of the gate electrode 2 face each other with the gate insulating film 5 disposed therebetween within a range where the outer peripheral surface 6a of the first electrode 6 and the inner peripheral surface 2a of the gate electrode 2 face each other as shown in a cross-sectional view of FIG. 7. The first electrode 6 can be formed by appropriately utilizing the formation material and the formation method described above for the gate electrode 2.

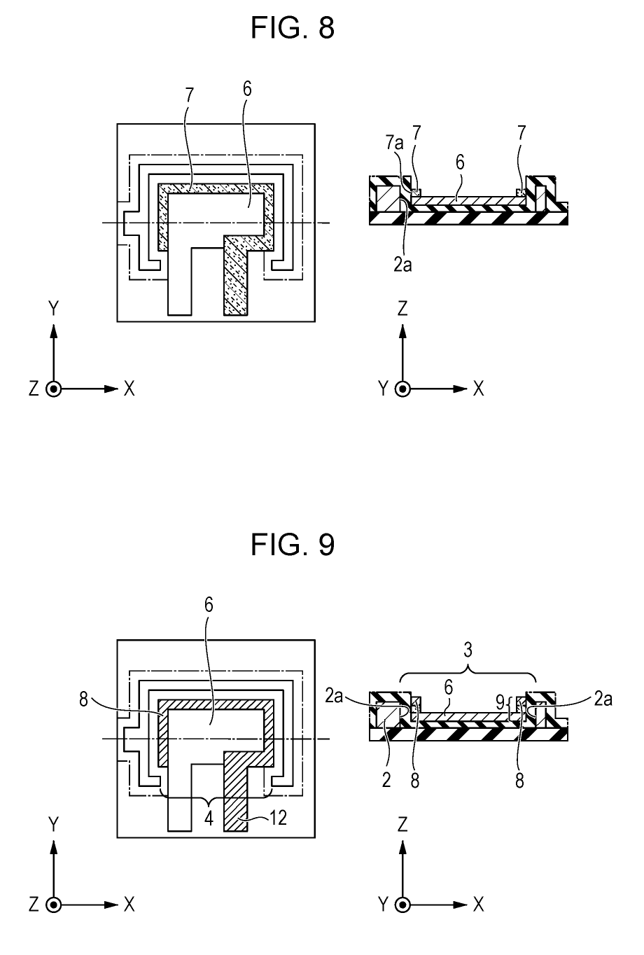

In the embodiment, the organic semiconductor film 7 is provided on the first electrode 6 so as to be in contact with the first electrode 6. The outer peripheral surface 7a of the organic semiconductor film 7 and the inner peripheral surface 2a of the gate electrode 2 face each other with the gate insulating film 5 disposed therebetween. The gate electrode 2 can apply an electric field to the organic semiconductor film 7 through the gate insulating film 5. As shown in FIG. 8, the organic semiconductor film 7 according to the embodiment is provided on the outer edge portion of the first electrode 6. In the embodiment, the top of a central portion of the first electrode 6 is a region on which the organic semiconductor film 7 is not formed. As shown in FIGS. 4 and 8, the organic semiconductor film 7 according to the embodiment is provided to extend from the top of the first electrode 6 to the top of the gate insulating film 5 outside the first electrode 6.

In general, organic semiconductor films are roughly classified into p-type and n-type semiconductors according to difference in carriers conducted in the films. Examples of p-type organic semiconductors containing holes as carriers include polycyclic aromatic hydrocarbon materials such as pentacene, anthracene, and rubrene, derivatives such as 6,13-bis(triisopropylsilylethynyl)pentacene (TIPS-pentacene) represented by chemical formula (2) below, phthalocyanines, heterocyclic conjugated materials such as oligothiophene and derivatives thereof, and polymeric materials such as poly-3-hexylthiophene (P3HT) represented by chemical formula (3) below and polyparaphenylene (PPV).

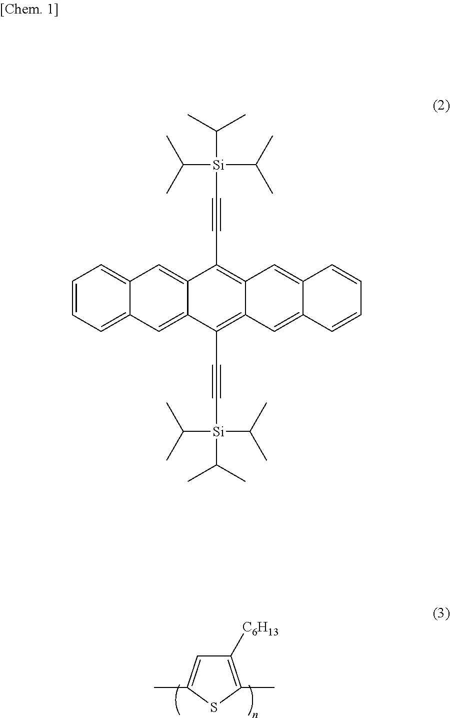

Examples of n-type organic semiconductor materials containing electrons as carriers include carbon-based materials such as fullerene (C60), carbon nanotubes, and the like, and materials having electron-attracting terminal substituents, for example, perfluorinated phthalocyanine represented by chemical formula (4) below, perfluorinated pentacene represented by chemical formula (5) below, and the like.

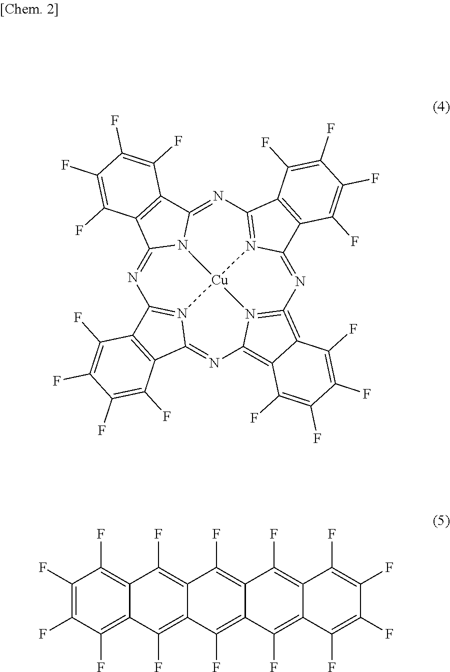

Also, as an organic semiconductor film, an organic molecular film or laminated film can be used, in which aromatic molecules, thiophene oligomers, or the like, which have a π-conjugated system, are aligned in a carrier conduction direction connecting the first electrode 6 and the second electrode 8 shown in FIG. 2. The use of such a material facilitates the movement of carriers between the first electrode 6 and the second electrode 8 through the organic semiconductor film, and thereby improvement in mobility and drain current can be expected.

The organic semiconductor film can be formed using a method such as a vacuum deposition method, a coating method using spin coating, a printing method using an ink jet apparatus, a film transfer apparatus, or the like. An aligned organic molecular film, for example, a Langmuir-Blodgett film (LB film), a self-assembled monolayer using organic semiconductor molecules, or the like, can be formed on a substrate directly or indirectly through film transfer.

As shown in FIGS. 1 and 2, the second electrode 8 according to this embodiment is provided on the organic semiconductor film 7 so as to be in contact with the organic semiconductor film 7. That is, the organic semiconductor film 7 is placed between the first electrode 6 and the second electrode 8 in the lamination direction of the laminate 9. The second electrode 8 according to this embodiment is provided on the outer edge of the first electrode 6. In the embodiment, the top of a central portion of the first electrode 6 is a region where the second electrode 8 is not formed. That is, the area of the first electrode 6 is larger than the area of the second electrode 8. The area of a region where the first electrode 6 and the second electro 8 overlap each other in the lamination direction of the laminate 9 is smaller than a larger one (here, the area of the first electrode 6) among the areas of the first electrode 6 and the second electrode 8. The second electrode 8 can be formed appropriately using the formation material and formation method described for the gate electrode 2.

The first wiring portion 11 is electrically connected to the first electrode 6. In the embodiment, the first wiring portion 11 is formed integrally using the same formation material as the first electrode 6. In the embodiment, in a film (hereinafter referred to as a “first conductive film”) constituting the first electrode 6 and the first wiring portion 11, a portion inside the predetermined region 3 is the first electrode 6, and a portion outside the predetermined region 3 is the first wiring portion 11. The first wiring portion 11 is disposed so as not to cross the gate electrode 2. The first wiring portion 11 is provided to extend to the outside of the predetermined region 3 through the notch portion 4.

The second wiring portion 12 is electrically connected to the second electrode 8. In the embodiment, the second wiring portion 12 is formed integrally using the same formation material as the second electrode 8. In the embodiment, in a film (hereinafter referred to as a “second conductive film”) constituting the second electrode 8 and the second wiring portion 12, a portion inside the predetermined region 3 is the second electrode 8, and a portion outside the predetermined region 3 is the second wiring portion 12. Both the second electrode 8 and the second wiring portion 12 are disposed so as not to cross the gate electrode 2. In the embodiment, the second wiring portion 12 is disposed so as not to overlap the first wiring portion 11 in a direction normal to the substrate surface 1a. The second wiring portion 12 is provided to extend on a portion of the organic semiconductor film 7, which is provided outside the predetermined region 3, to the outside of the predetermined region 3 through the notch portion 4.

The first wiring portion 11 may be composed of a film formed separately from the first electrode 6. In this case, the first wiring portion 11 may be provided to extend from the outside to the inside of the predetermined region 3 and to be in contact with the first electrode 6. The second wiring portion 12 may be composed of a film formed separately from the second electrode 8. In this case, the second wiring portion 12 may be provided to extend from the outside to the inside of the predetermined region 3 and to be in contact with the second electrode 8. The first wiring portion 11 and the second wiring portion 12 can be formed appropriately using the formation material and formation method described for the gate electrode 2.

Next, an example of a method for manufacturing the organic semiconductor device according to the first embodiment is described, but the application scope of the embodiment is not limited to the manufacturing method described below.

As shown in FIG. 5, the manufacturing method of this example includes a step of forming the gate electrode 2 on the insulating substrate 1 using the above-described conductive material. In this example, the insulating substrate 1 is a glass substrate. The gate electrode 2 of this example is composed of an alloy containing 99% by weight of aluminum and 1% by weight of silicon and has a thickness of about 300 nm. The gate electrode 2 of this example is formed by depositing the alloy over substantially the entire region of the substrate surface 1a of the insulating substrate 1 by a sputtering method and then patterning the resultant film using a photolithography method and an etching method. The patterning is performed so that the gate electrode 2 has a shape in which the notch portion 4 is provided in a circumferential portion of a frame.

As shown in FIG. 6, the manufacturing method of this example includes a step of forming the gate insulating film 5 to cover the surface of the gate electrode 2. The gate insulating film 5 of this example is composed of silicon oxide (SiO₂) and has a thickness of about 100 nm. The gate insulating film 5 of this example is formed by depositing silicon oxide to cover the surface of the gate electrode 2 and substantially the entire region of the substrate surface 1a of the insulating substrate 1 by a sputtering method.

As shown in FIG. 7, the manufacturing method of this example includes a step of forming the first conductive film on the insulating substrate 1 on which the gate insulating film 5 has been formed, the first conductive film including the first electrode 6 and the first wiring portion 11 electrically connected to the first electrode 6. The first electrode 6 is formed inside the predetermined region 3 so as to be in contact with a portion of the gate insulating film 5, which covers the inner peripheral surface 2a of the gate electrode 2. The first wiring portion 11 is formed to continue from the first electrode 6 and extend to the outside of the gate electrode 2 through the notch portion 4.

The first electrode 6 and the first wiring portion 11 of this example each have a first layer formed on the gate insulating film 5 and a second layer formed on the first layer. A material which forms the first layer is selected from, for example, materials having higher adhesion to the gate insulating film 5 than the formation material of the second layer. A material which forms the second layer is selected from, for example, materials having higher dielectric constant than the formation material of the first layer. The thickness of the second layer is determined to, for example, a value larger than the thickness of the first layer.

The first layer of this example is composed of chromium and has a thickness of about 3 nm. The second layer of this example is composed of gold and has a thickness of about 80 nm. The first layer of this example is formed using a metal mask having an aperture with a shape corresponding to the first electrode 1 plus first wiring portion 11 to be formed. The first layer of this example is formed by depositing chromium on the gate insulating film 5 by a vacuum deposition method through the metal mask which is aligned with the insulating substrate 1. The second layer of this example is formed by depositing gold on the first layer by a vacuum deposition method through the metal mask which is kept in alignment with the insulating substrate 1.

As shown in FIG. 8, the manufacturing method of this example includes a step of forming the organic semiconductor film 7 on the outer edge portion of the first electrode 6. The organic semiconductor film 7 of this example is formed to be continued from a portion of the upper surface of the first electrode 6 and the upper surface of the first wiring portion 11. The organic semiconductor film 7 of this example is formed to be in contact with a portion of the gate insulating film 5 which covers the inner peripheral surface 2a of the gate electrode 2. The organic semiconductor film 7 of this example is composed of a p-type organic semiconductor material and has a thickness of about 60 nm. The organic semiconductor film 7 of this example is formed using a metal mask having an aperture with the same shape as the organic semiconductor film 7. The organic semiconductor film 7 of this example is formed by depositing pentacene on the first electrode 6 by a vacuum deposition method through the metal mask aligned with the insulating substrate 1 on which the first electrode 6 has been formed.

As shown in FIG. 9, the manufacturing method of this example includes a step of forming the second electrode 8 and the second wiring portion 12 so that they fit on the organic semiconductor film 7. The second electrode 6 is formed inside the predetermined region 3 so as to be in contact with a portion of the gate insulating film 5 which covers the inner peripheral surface 2a of the gate electrode 2. The second wiring portion 12 is formed to continue from the second electrode 8 and to extend to the outside of the gate electrode 2 through the notch portion 4.

The second electrode 8 and the second wiring portion 12 of this example are composed of gold and have a thickness of about 80 nm. The second electrode 8 of this example is formed by depositing gold on the organic semiconductor film 7 by a vacuum deposition method through the metal mask used for forming the organic semiconductor film 7 and kept in alignment with the insulating substrate 1. That is, in this example, the shape corresponding to the second electrode 8 plus the second wiring portion 12 is substantially the same as the shape of the organic semiconductor film 7.

As described above, the organic thin-film transistor TR1 according to the first embodiment is formed, and the organic semiconductor device SD1 including the organic thin-film transistor TR1 is manufactured.

In the above-described organic semiconductor device SD1, for example, when the first electrode 6 and the second electrode 8 are considered as a source electrode and a drain electrode, respectively, of a general thin-film transistor, a gate voltage corresponding to the threshold voltage of the organic thin-film transistor TR1 and a drain voltage are applied to the gate electrode 2 and the second electrode 8, respectively, with the first electrode 6 being grounded, to inject carriers into the organic semiconductor film 7 from the first electrode 6, thereby forming a channel layer connecting the first electrode 6 and the second electrode 8 in an interface between the organic semiconductor film 7 and the gate insulating film 5. As a result, the organic thin-film transistor TR1 is turned on. In this state, the drain voltage is applied between the first electrode 6 and the second electrode 8, and thus a drain current flows to the organic semiconductor film 7 through the channel layer. As shown in the above-described formula (1), a theoretical drain current is inversely proportional to the channel length L and proportional to the channel width W.

The channel length L of the organic thin-film transistor TR1 corresponds to the thickness of the organic semiconductor film 7 and thus can be easily shortened. For example, the channel length L in a planar-type structure depends on patterning process accuracy, and the like, and in an organic thin-film transistor using an organic semiconductor having weak process resistance, the channel length L is about several to several tens μm. On the other hand, the thickness of the organic semiconductor film 7 can be set to about several tens to several hundreds nm by, for example, controlling the deposition time. Therefore, in the organic thin-film transistor TR1 according to the embodiment, the channel length L can be easily shortened to about 1/10 to 1/1000 as compared with the planar-type structure. Also, the channel width W of the organic thin-film transistor TR1 corresponds to the length of a portion where the organic semiconductor film 7 and the inner peripheral surface 2a of the gate electrode 2 face each other in a direction parallel to the substrate surface 1a of the insulating substrate 1. Since the gate electrode 2 extends to be bent in a direction parallel to the substrate surface 1a of the insulating substrate 1, the channel width W of the organic thin-film transistor TR1 can be easily increased. As described above, in the organic thin-film transistor TR1 according to the embodiment, the drain current can be easily increased.

The gate electrode 2 according to the embodiment is provided to surround the outer periphery of the laminate 9 except in a portion corresponding to the notch portion 4. In addition, the first wiring portion 11 and the second wiring portion 12 are drawn out to the outside of the gate electrode 2 through the notch portion 4. Therefore, the gate electrode 2 does not cross any one of the first electrode 6, the first wiring portion 11, the second electrode 8, and the second wiring portion 12. Therefore, the occurrence of wiring disconnection or the like in an overlap portion due to a step difference of an underlying base can be suppressed as compared with a structure having an overlap portion between a gate electrode and wiring or a gate electrode and an electrode. As a result, the organic semiconductor device SD1 according to the embodiment is capable of suppressing a decrease in yield.

In the embodiment, the area of the first electrode 6 is different from the area of the second electrode 8. The area of a region where the first electrode 6 and the second electrode 8 overlap each other in the lamination direction of the laminate 6 is smaller than a larger one among the areas of the first electrode 6 and the second electrode 8. As the area of a region where the first electrode 6 and the second electrode 8 overlap each other decreases, a leakage current and parasitic capacitance between the first electrode 6 and the second electrode 8 decrease. Therefore, in an organic thin-film transistor TR1 according to the embodiment, a leakage current and parasitic capacitance can be decreased.

The gate insulating film 5 according to the embodiment is formed over substantially the entire region of the substrate surface 1a of the insulating substrate 1 so as to continuously cover substantially the entire region of the upper surface and side surface of the gate electrode 2. In addition, the laminate 9 is formed on the gate insulating film 5. Therefore, the occurrence of a defect, due to the formation of short-circuiting between a portion of the laminate 9 and the gate electrode 2 can be suppressed. Further, fine pattern formation process of the gate insulating film 5 is not needed.

The organic semiconductor film 7 according to the embodiment is also formed below the second wiring portion 12 drawn out from the second electrode 8. Therefore, a step difference of an underlying base below a portion in which wiring is electrically drawn out by the second wiring portion 12 from the second electrode 8 corresponds to the thickness of the first electrode 6, thereby reducing the occurrence of wiring disconnection or the like. In addition, in the above-described example of the manufacturing method, the second conductive film constituting the second electrode 8 and the second wiring portion 12 is formed in succession to the formation of the organic semiconductor film 7 while the mask used for forming the organic semiconductor film 7 is kept in alignment with the insulating substrate 1. Therefore, the occurrence of lamination shift between the organic semiconductor film 7 and the second conductive film can be suppressed. Also, in the above-described example of the manufacturing method, the step of aligning another mask different from the mask for forming the organic semiconductor film 7 can be omitted as compared with a method for forming the second conductive film using the other mask, thereby improving the manufacturing efficiency of the organic semiconductor device SD1.

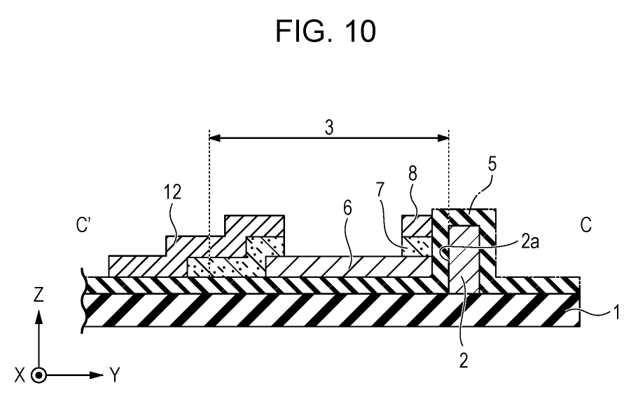

Next, modified examples 1 to 3 are described. FIG. 10 is a cross-sectional view of an organic semiconductor device according to the modified example 1. FIG. 10 shows a section taken along a line corresponding to line C-C′ in FIG. 1. The organic semiconductor film 7 of the modified example 1 is provided to extend from the top of the first electrode 6 to the top of the gate insulating film 5 outside the first electrode 6. The second conductive film is provided to extend from the top of a portion of the organic semiconductor film 7, which is provided to extend to the outside of the first electrode 6, to the top of the gate insulating film 5 outside the organic semiconductor film 7.

In addition, a step difference corresponding to the total thickness of the first electrode 6 and the organic semiconductor film 7 is present between the upper surface of the gate insulating film 5 and the upper surface of the organic semiconductor film 7 on the first electrode 6. In the modified example 1, the second conductive film crosses over a step difference corresponding to the thickness of the first electrode 6 near the edge of the first electrode 6 and also crosses over a step difference corresponding to the thickness of the organic semiconductor film 7 near the edge of the organic semiconductor film 7. Thus, each of the steps which the second conductive film crosses over is a divided part of the step difference from the upper surface of the organic semiconductor film 7 on the first electrode 6 to the upper surface of the gate insulating film 5. Therefore, the second conductive film does not cross over a large step at a time, and thus the occurrence of wiring disconnection or the like can be reduced.

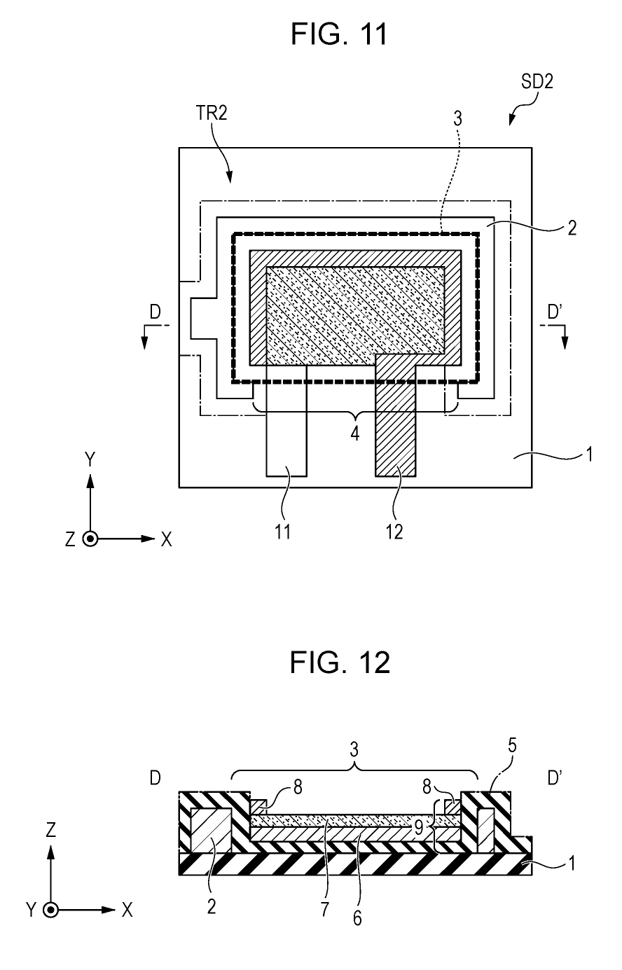

FIG. 11 is a plan view of an organic semiconductor device according to the modified example 2. FIG. 12 is a cross-sectional view taken along line D-D′ in FIG. 11. An organic semiconductor device SD2 shown in FIGS. 11 and 12 includes an insulating substrate 1, an organic thin-film transistor TR2, a first wiring portion 11, and a second wiring portion 12. In the modified example 2, the area of the first electrode 6 is larger than the area of the second electrode 8. In the modified example 2, the organic semiconductor film 7 is continued from a region where the first electrode 6 and the second electrode 8 overlap each other in the lamination direction of the laminate 9 to a region surrounded by that region. In the upper surface of the organic semiconductor film 7, the outer edge portion adjacent to the notch portion 4 is a region where the second conductive film constituting the second electrode 8 and the second wiring portion 12 are formed. In the upper surface of the organic semiconductor film 7, a region inside the outer edge portion is a region where the second conductive film is not formed.

In the organic thin-film transistor TR2 according to the modified example 2, the area of the first electrode 6 and the area of the second electrode 8 within the predetermined region 3 are different, and thus the area of a region where the first electrode 6 and the second electrode 8 overlap each other in the lamination direction of the laminate 9 can be decreased. Therefore, the organic thin-film transistor TR2 is capable of decreasing a leakage current and parasitic capacitance. In addition, the organic semiconductor film 7 is also formed inside the region where the first electrode 6 and the second electrode 8 overlap each other in the lamination direction of the laminate 9, thereby causing little defect formed by short-circuiting between the second electrode 8 and the first electrode 6.

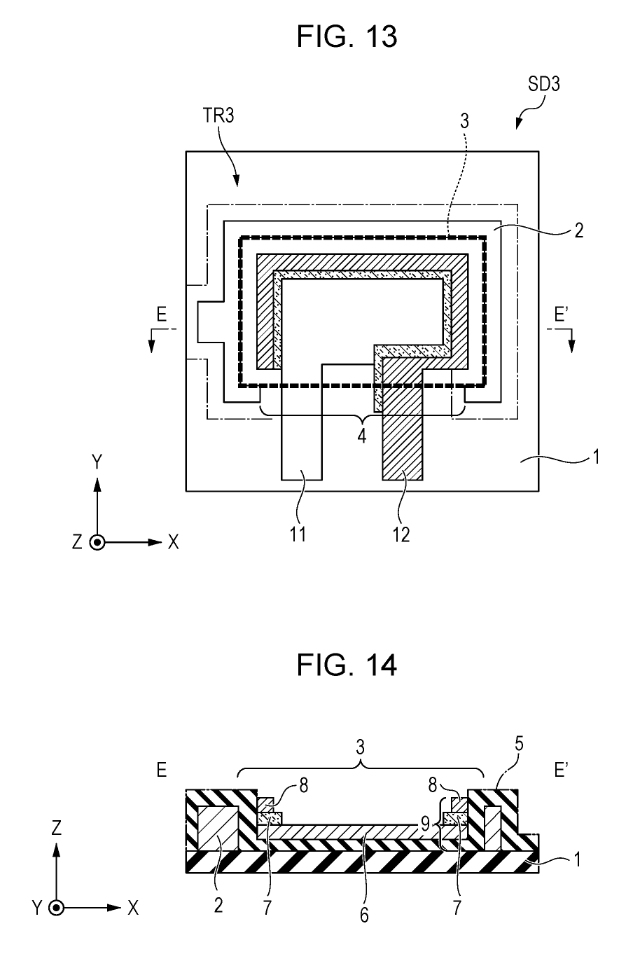

FIG. 13 is a plan view of an organic semiconductor device according to the modified example 3. FIG. 14 is a cross-sectional view taken along line E-E′ in FIG. 13. An organic semiconductor device SD3 shown in FIGS. 13 and 14 includes an insulating substrate 1, an organic thin-film transistor TR3, a first wiring portion 11, and a second wiring portion 12.

In the modified example 3, the area of the first electrode 6 is larger than the area of the second electrode 8. In the modified example 3, the upper surface of a central portion of the first electrode 6 is a region where the organic semiconductor film 7 is not formed. In the modified example 3, the upper surface of the organic semiconductor film 7 includes a region where the second electrode 8 is not formed. In the organic thin-film transistor TR3 according to the modified example 3, the area of the first electrode 6 is different from the area of the second electrode 8 within the predetermined region 3, and thus the area of a region where the first electrode 6 and the second electrode 8 overlap each other in the lamination direction of the laminate 9 can be decreased. Therefore, the organic thin-film transistor TR3 is capable of decreasing a leakage current and parasitic capacitance. Further, the organic semiconductor film 7 is formed with a larger area than that of the second electrode 8 formed thereon so as to include the region where the second electrode 8 is not formed, thereby causing little defect of short-circuiting between the second electrode 8 and the first electrode 6 like in the modified example 2.

### Second Embodiment

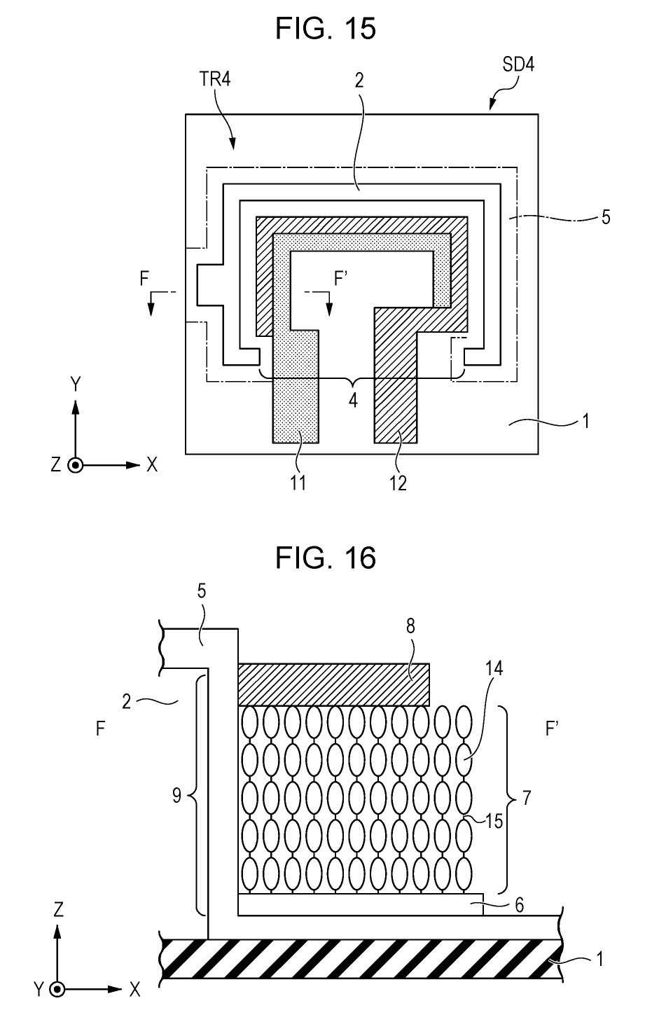

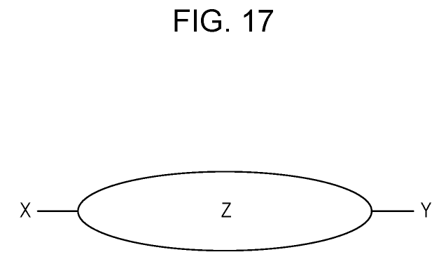

Next, a second embodiment is described. FIG. 15 is a plan view of an organic semiconductor device according to the second embodiment. FIG. 16 is a cross-sectional view take along line F-F′ in FIG. 15. FIG. 17 is an explanatory view illustrating an example of π-conjugated organic molecules.

An organic semiconductor device SD4 shown in FIGS. 15 and 16 includes an insulating substrate 1, an organic thin-film transistor TR4, a first wiring portion 11, and a second wiring portion 12. An organic semiconductor film 7 of the organic thin-film transistor TR4 contains π-conjugated molecules aligned in a direction connecting the first electrode 6 and the second electrode 8. In detail, an organic molecular layer having a structure in which organic molecules 14 are bonded to each other through chemical bond 15 is formed on the first electrode 6 formed on the gate insulating film 5. As shown in FIG. 17, the organic molecules 14 according to the embodiment have a structure in which functional group X and functional group Y for forming the chemical bonds 15 are provided at both ends of organic molecule Z having functionality.

The organic molecule Z is a π-conjugated molecule showing semiconductor properties. Examples of the organic molecule Z include π-conjugated molecules such as 6-membered ring compounds, e.g., stilbene represented by formula (6) below, benzene represented by formula (7) below, biphenyl represented by formula (8) below, bispyridylethylene represented by formula (10) below, pyridine represented by formula (11) below, bipyridine represented by formula (12) below, and the like; 5-membered ring compounds, e.g., thiophene represented by formula (9) below, oxadiazole represented by formula (13), triazole, and the like; and oligomers thereof. When the organic molecule Z is benzene or pyridine, the functional group X and the functional group Y are preferably positioned at the 1- and 4-positions; when the organic molecule Z is stilbene, biphenyl, bispyridylethylene, or bipyridine, the 4- and 4′-positions; and when the organic molecule Z is thiophene, oxadiazole, or triazole, the 2- and 5-positions.

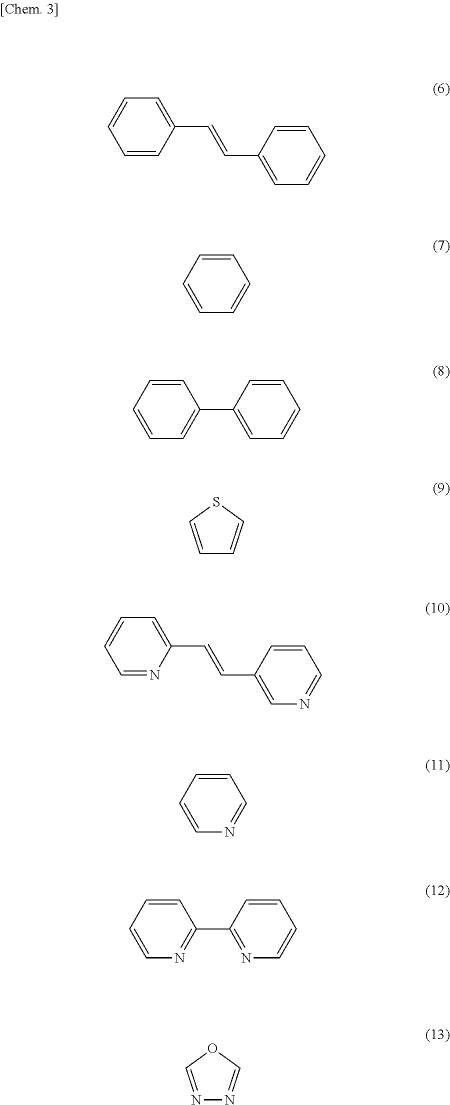

Examples of the functional group X and the functional group Y to be combined with the organic molecule Z include a silane coupling group (—SiR′₃), a phosphonic acid group (—POR″₂), a phosphate carboxyl group (—COR″), a sulfonic acid group (—SO₃R″), an amino group (—NH₂), an isocyanate group (—NCO), a thiol group (—SH), a nitrile group (—CN), and the like. Any one of R's is —OMe, —OEt, or —Cl. Any one of R″s is —OH or —Cl.

Examples of the chemical bonds 15 formed by the functional group X and the functional group Y, e.g., examples of a chemical bond with the first electrode 6, include a thiol bond, a siloxane bond, a phosphate bond, an ester bond, a sulfonate bond, a sulfide bond, and the like. Examples of a bond between the organic molecules 14 include an amide bond, an imine bond, an imide bond, a urethane bond, a urea bond, and the like.

These organic molecules 14 are repeatedly bonded to each other through the chemical bonds 15 in a direction from the first electrode 6 to the second electrode 8. That is, the organic semiconductor film 7 has a structure in which the π-conjugated organic molecules 14 are aligned in a direction from the first electrode 6 to the second electrode 8.

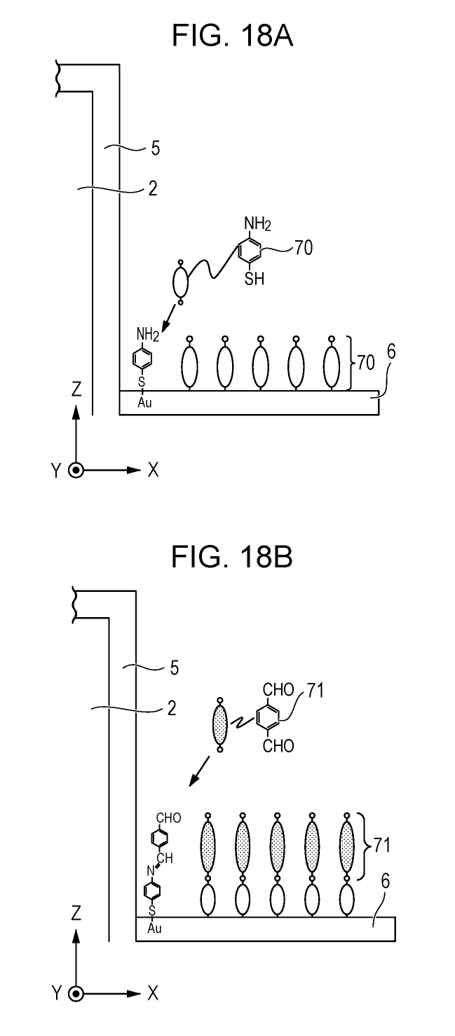

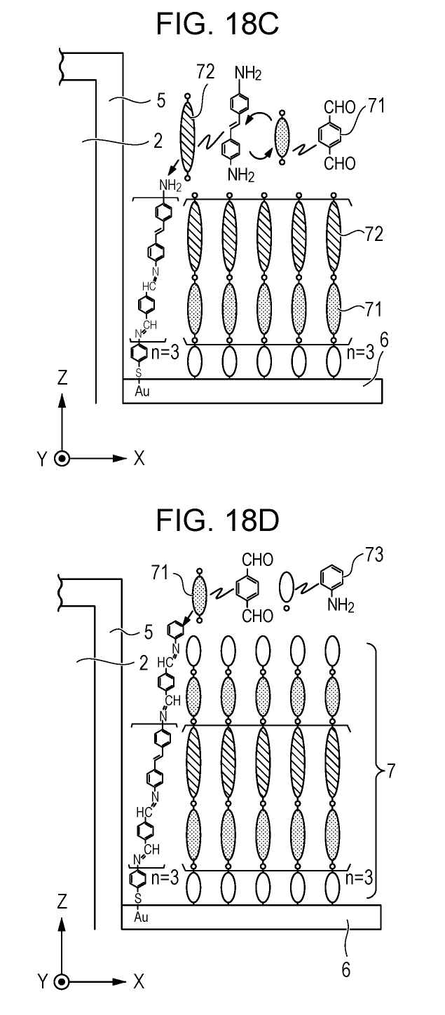

Next, an example of a method for manufacturing the organic semiconductor device according to the second embodiment is described, but the application scope of the embodiment is not limited to a manufacturing method described below. FIGS. 18A to 18D are process cross-sectional views showing an example of the method for manufacturing the organic semiconductor device according to the second embodiment.

The manufacturing method of this example includes a step of forming the gate electrode 2 on the insulating substrate 1, a step of forming the gate insulating film 5 to cover the surface of the gate electrode 2, and a step of forming the first conductive film, which includes the first electrode 6 and the first wiring portion 11 electrically connected to the first electrode 6, on the insulating substrate 1 on which the gate insulating film 5 has been formed. The steps of the manufacturing method described in the first embodiment can be applied to these steps. The gate electrode 2 of this example is composed of aluminum. The gate insulating film 5 of this example is composed of silicon oxide. The first conductive film (the first electrode 6 and the first wiring portion 11) of this example is composed of gold and has a thickness of about 60 nm. The first conductive film of this example is formed by, for example, a mask vacuum deposition method.

The manufacturing method of this example further includes a step of forming the organic semiconductor film 7 on the first conductive film. In this example, the organic semiconductor film 7 is formed by using two or more types of organic molecules each having the functional group X, the functional group Y, and the organic molecule Z. The functional group X of a first organic molecule may be the same as or different from the functional group Y of the first organic molecule. The first organic molecule is selected so as to suppress reaction between the functional group X of the first organic molecule and the functional group Y of the first organic molecule under predetermined conditions. The functional group X of a second organic molecule may be the same as or different from the functional group Y of the second organic molecule. The second organic molecule is selected so as to allow reaction between the functional group X or the functional group Y of the first organic molecule and the functional group X or the functional group Y of the second organic molecule to proceed under predetermined conditions.

The organic semiconductor film 7 of this example is formed by using four types of organic molecules. A first organic molecule 70 of this example is 4-aminobenzenethiol represented by formula (14) below. 4-Aminobenzenethiol contains a thiol group (—SH) as the functional group X, an amino group (—NH₂) as the functional group Y, and a benzene ring as the organic molecule Z. A second organic molecule 71 of this example is terephthalaldehyde represented by formula (16) below. Terephthalaldehyde contains aldehyde groups (—CHO) as the functional group X and the functional group Y, and a benzene ring as the organic molecule Z. A third organic molecule 72 of this example is stilbenediamine having amino groups at both ends of a stilbene skeleton as shown in formula 15 below. A fourth organic molecule 73 of this example is aniline shown in formula 17 below.

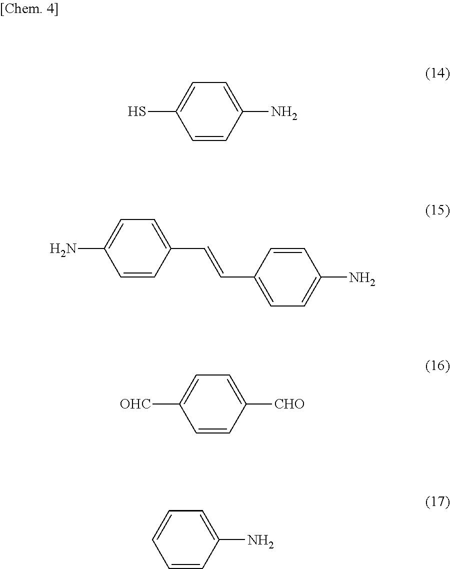 [SMILES: Nc1ccc(S)cc1 ; Nc1ccc(/C=C/c2ccc(N)cc2)cc1 ; O=Cc1ccc(C=O)cc1 ; Nc1ccccc1]

In order to form the organic semiconductor film 7 of this example, first, as shown in FIG. 18A, a self-assembled monolayer (first layer) composed of the first organic molecule 70 is formed on the surface of the first electrode 6. In this example, a methanol solution (concentration of 1 mM) of 4-aminobenzenethiol is prepared, and the insulating substrate 1 on which the first electrode 6 has been formed is immersed in the solution at room temperature for 24 hours. In this example, the thiol group of the first organic molecule 70 is bonded to the surface (gold) of the first electrode 6 to form the first layer. In this example, after reaction of the thiol group with the surface of the first electrode 6, the insulating substrate 1 pulled up from the solution is washed with methanol to remove excessive 4-aminobenzenethiol molecules not bonded to the surface of the first electrode 6. As a result, the surface of the first electrode 6 is coated with 4-aminobenzenethiol. In addition, the amino group opposite to the thiol group is exposed in the surface of the first layer on the side opposite to the first electrode 6.

In the above-described step, the materials of the constituent elements and the first organic molecule are selected so that, other than the first electrode 6, the constituent elements exposed to the solution do not react with the functional group X and the functional group Y of the first organic molecule, thereby permitting the formation of a self-assembled monolayer only on the surface of the first electrode 6. In this example, 4-aminobenzenethiol hardly reacts with both the gate electrode 2 composed of aluminum and the gate insulating film 5 composed of silicon oxide.

Then, as shown in FIG. 18B, the second organic molecule 71 is reacted with the surface (amino group) of the first layer to form a self-assembled monolayer (second layer) composed of the second organic molecule 71. In this example, an ethanol solution (concentration of 1 mM) of terephthalaldehyde is prepared, and the insulating substrate 1 on which the first layer has been formed is immersed in the solution at room temperature for 12 hours under stirring of the solution. In this example, the amino group of the first layer reacts with the aldehyde group of the second organic molecule 71 to form the second layer through an imine bond. In this example, after reaction of the amino group with the aldehyde group, the insulating substrate 1 pulled up from the solution is washed with ethanol to remove terephthalaldehyde not chemically bonded to the first layer. As a result, the surface of the first layer is coated with terephthalaldehyde. In addition, the aldehyde group is exposed in the surface of the second layer on the side opposite to the first layer. In addition, terephthalaldehyde hardly reacts with both the gate electrode 2 composed of aluminum and the gate insulating film 5 composed of silicon oxide, thereby forming the second layer substantially only on the first layer.

Then, as shown in FIG. 18C, the third organic molecule 72 is reacted with the surface (aldehyde group) of the second layer to form a self-assembled monolayer (third layer) composed of the third organic molecule 72. In this example, an ethanol solution (concentration of 1 mM) of stilbenediamine is prepared, and the insulating substrate 1 on which the first layer has been formed is immersed in the solution at room temperature for 12 hours under stirring of the solution. In this example, the aldehyde group of the second layer is reacted with the amino group of the third organic molecule 72 to form the third layer through an imine bond. In this example, after reaction of the amino group with the aldehyde group, the insulating substrate 1 pulled up from the solution is washed with ethanol to remove stilbenediamine not chemically bonded to the second layer. As a result, the surface of the second layer is coated with stilbenediamine. In addition, the amino group is exposed in the surface of the third layer on the side opposite to the second layer. In addition, stilbenediamine hardly reacts with both the gate electrode 2 composed of aluminum and the gate insulating film 5 composed of silicon oxide, thereby forming the third layer substantially only on the second layer. In this example, a self-assembled monolayer (fourth layer, sixth layer, . . . ) composed of the second organic molecule 71 and a self-assembled monolayer (fifth layer, seventh layer, . . . ) composed of the third organic molecule 72 are alternately formed on the third layer 3 composed of the third organic molecule 72. In this example, a self-assembled monolayer is repeatedly formed so that an aldehyde group is exposed in the outermost surface of the insulating substrate 1 on which the self-assembled monolayers have been formed and the total thickness of a plurality of self-assembled monolayers is a predetermined thickness.

Then, as shown in FIG. 18D, the fourth organic molecule 73 is reacted with the outermost surface (aldehyde group) to form a self-assembled monolayer (eighth layer) composed of the fourth organic molecule 73. In this example, an ethanol solution (concentration of 1 mM) of aniline is prepared, and the insulating substrate 1 on which the seventh layer has been formed is immersed in the solution at room temperature for 12 hours under stirring of the solution. In this example, the aldehyde group of the seventh layer is reacted with the amino group of the fourth organic molecule 73 to form the eighth layer through an imine bond. In this example, after reaction of the amino group with the aldehyde group, the insulating substrate 1 pulled up from the solution is washed with ethanol to remove aniline not chemically bonded to the second layer. As a result, the surface of the seventh layer is coated with aniline. In addition, the surface of the eighth layer on the side opposite to the seventh layer is terminated with a benzene ring. In addition, aniline hardly reacts with both the gate electrode 2 composed of aluminum and the gate insulating film 5 composed of silicon oxide, thereby forming the eighth layer substantially only on the seventh layer.

The total thickness of the organic semiconductor film 7 formed as described above is, for example, about 7.5 nm. In addition, the second electrode 8 composed of, for example, gold is formed on the organic semiconductor film 7 to form the organic thin-film transistor TR4 of this example. The second electrode 8 of this example is formed by, for example, a mask vacuum deposition method.

As described in the first embodiment, the organic semiconductor device SD4 of the second embodiment is capable of increasing a drain current, decreasing a parasitic capacitance and leakage current, and suppressing the occurrence of wiring disconnection due to a step difference. Also, in this embodiment, the organic semiconductor film 7 is composed of π-conjugated organic molecules which are aligned in a direction connecting the first electrode 6 and the second electrode 8 and are connected to each other through chemical bonds. In each of the π-conjugated organic molecules, π-conjugation extends along the molecular long axis, and thus the drain current can be further increased by aligning the molecular long axis with the thickness direction in which the drain current flows in a vertical thin-film transistor. Also, each of the organic molecules 14 is bonded to the surface of the first electrode 6 or another organic molecule through chemical bond. Therefore, it is possible to improve resistance to deterioration in the organic semiconductor film due to electromigration caused by electric field application or current conduction, the occurrence of defects such as disturbance of molecular alignment and the like. In addition, peeling of the film or the like little occurs due to stress, such as bending, deformation, or the like, and thus a flexible substrate such as a resin substrate with flexibility can be used as, for example, the insulating substrate 1.

### Third Embodiment

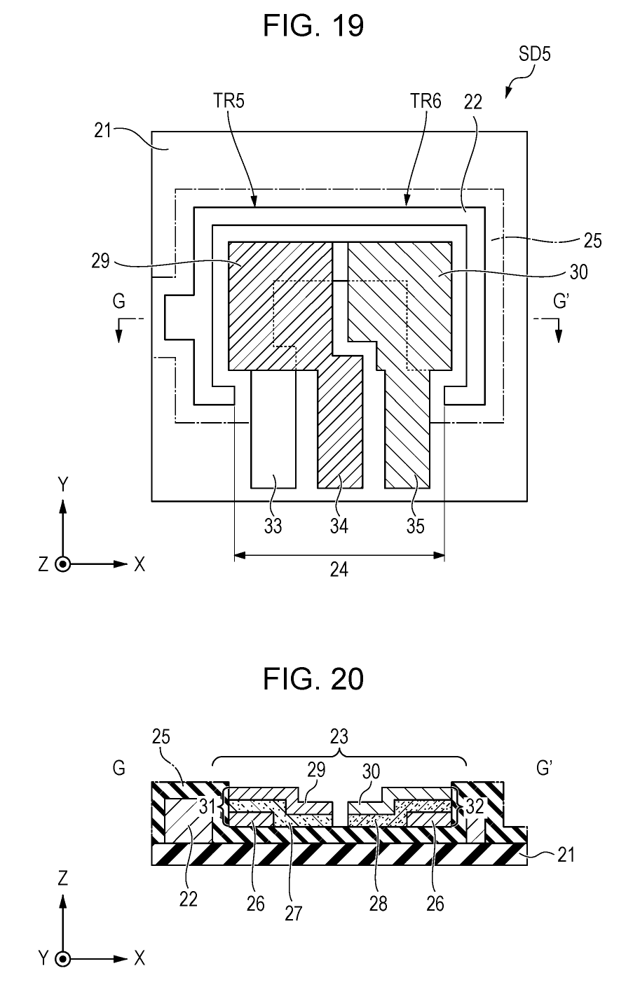

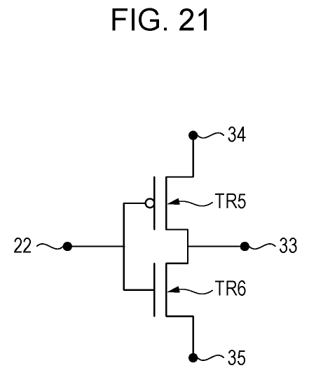

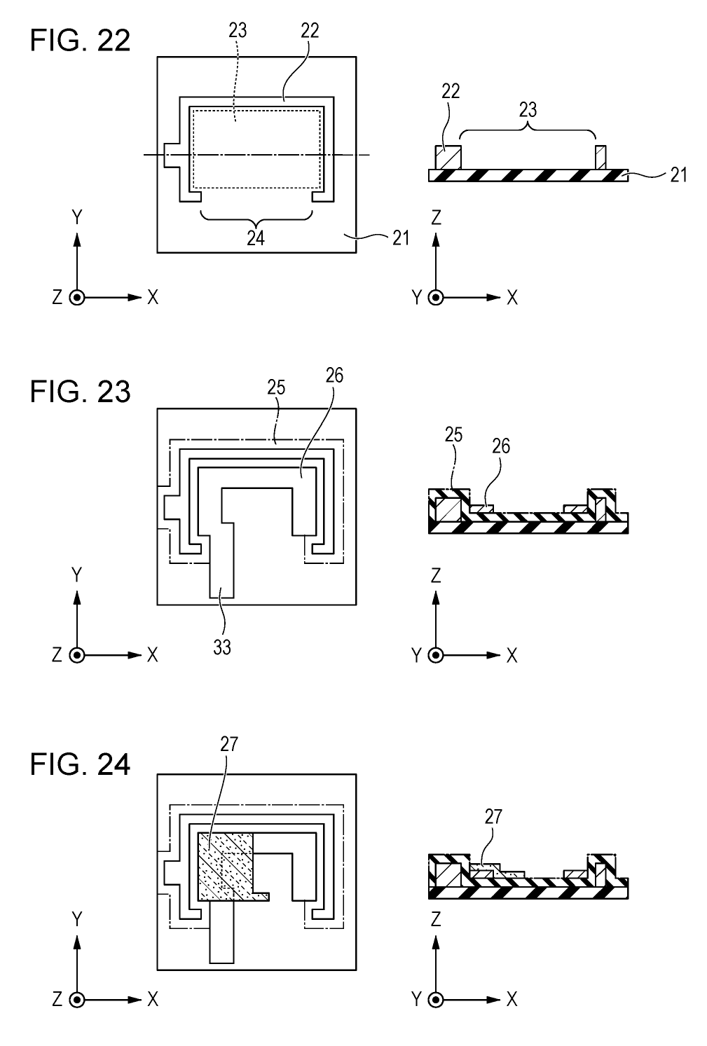

Next, a third embodiment is described. FIG. 19 is a plan view of an organic semiconductor device according to the third embodiment. FIG. 20 is a cross-sectional view take along line G-G′ in FIG. 19. FIG. 21 is an equivalent circuit diagram of the organic semiconductor device according to the third embodiment. FIGS. 22 to 26 are process views showing an example of a method for manufacturing the organic semiconductor device according to the third embodiment. FIGS. 22 to 26 are each a process plan view (view on the left) and a process cross-sectional view (view on the right) taken along a one-dot chain line in the process plan view.

An organic semiconductor device SD5 shown in FIGS. 19 to 21 is a so-called CMOS circuit. The organic semiconductor device SD5 includes an insulating substrate 21, a first organic thin-film transistor TR5, a second organic thin-film transistor TR6, a first wiring portion 33, a second wiring portion 34, and a third wiring portion 35. The insulating substrate 21 has at least one insulating surface (substrate surface). The insulating substrate 21 is a substrate properly selected from the substrates described in the first embodiment. The first organic thin-film transistor TR5, the second organic thin-film transistor TR6, the first wiring portion 33, the second wiring portion 34, and the third wiring portion 35 are formed on the insulating substrate 21. The first wiring portion 33 is electrically connected to a first electrode 26 common to the first organic thin-film transistor TR5 and the second organic thin-film transistor TR6. The second wiring portion 34 is electrically connected to a second electrode 29 of the first organic thin-film transistor TR5. The third wiring portion 35 is electrically connected to a third electrode 30 of the second organic thin-film transistor TR6.

The first organic thin-film transistor TR5 includes a gate electrode 22, a first laminate 31, and a gate insulating film 25. The first laminate 31 has the first electrode 26, a first organic semiconductor film 27, and the second electrode 29, which are laminated with each other in a direction normal to the substrate surface of the insulating substrate 21. The second organic thin-film transistor TR6 includes the gate electrode 22, a second laminate 32, and the gate insulating film 25. The second laminate 32 has the first electrode 26, a second organic semiconductor film 28, and the third electrode 30 which are laminated with each other in a direction normal to the substrate surface of the insulating substrate 21. That is, in this embodiment, the gate electrode 22, the gate insulating film 25, and the first electrode 26 are common to the first organic thin-film transistor TR5 and the second organic thin-film transistor TR6.

The first organic thin-film transistor TR5 and the second organic thin-film transistor TR6 have the common first electrode 26 and are thus electrically connected to each other. In the third embodiment, each of the electrodes, wirings, and gate insulating film can be formed by the same formation method using the same forming material as described in the first embodiment.

As shown in FIG. 22, the gate electrode 22 is disposed adjacent to the periphery of a predetermined region 23 and outside the predetermined region 23 on the insulating substrate 21. The gate electrode 22 is provided around the predetermined region 23 except in a region (notch portion 24) adjacent a portion of the periphery of the predetermined region 23 so as to surround the predetermined region 23. When a direction crossing a first direction (X direction in the drawing) in which the first laminate 31 and the second laminate 32 are arranged is regarded as a second direction (Y direction in the drawing), the notch portion 24 of the embodiment is disposed in the second direction with respect to the first laminate 31 and the second laminate 32. The gate electrode 22 extends to be bent along the periphery of the predetermined region 23. The gate electrode 22 according to this embodiment has the same shape as the gate electrode 22 described in the first embodiment.

As shown in FIG. 20, the first laminate 31 and the second laminate 32 are disposed inside the predetermined region 23 and apart at a distance corresponding to the thickness of the gate insulating film 25 from the outer periphery of the predetermined region 23. The first laminate 31 and the second laminate 32 are arranged in the first direction (X direction in the drawing). The gate insulating film 25 is provided at least between the gate electrode 22 and the first laminate 31 and between the gate electrode 22 and the second laminate 32. In this embodiment, the gate insulating film 25 is provided over substantially the entire region of one of the surfaces of the insulating substrate 1 so as to cover the gate electrode 22. The first laminate 31 and the second laminate 32 are provided on the gate insulating film 25 so as to be disposed inside the predetermined region 23.

In this embodiment, the first electrode 26 is provided on the gate insulating film 25 so as to be in contact with the gate insulating film 25. The first electrode 26 according to this embodiment is continued over a region where the first laminate 31 is disposed and a region where the second laminate 32 is disposed. As shown in FIG. 23, the first electrode 26 extends to be bent long the inner periphery of the gate electrode 22. In this embodiment, a central portion of the predetermined region 23 shown in FIG. 22 is a region where the first electrode 26 is not formed.

The first wiring portion 33 is electrically connected to the first electrode 26. In this embodiment, the first electrode 26 and the first wiring portion 33 are integrally formed using the same forming material. A first conductive film constituting the first electrode 26 and the first wiring portion 33 is provided to extend to the outside of the gate electrode 22 through the notch portion 24.

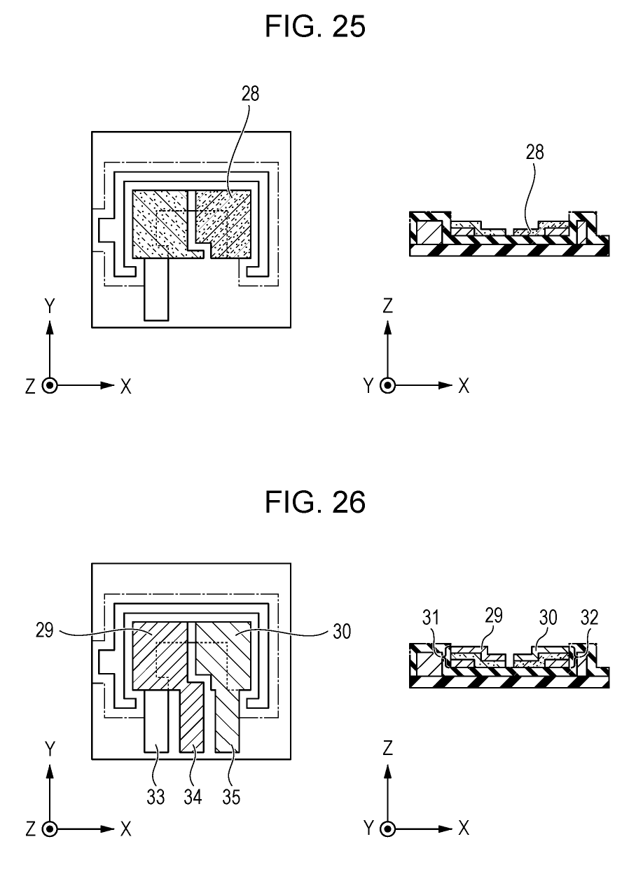

One of the first organic semiconductor film 27 of the first organic thin-film transistor TR5 and the second organic semiconductor film 28 of the second organic thin-film transistor TR6 is composed of a n-type semiconductor material, and the other is composed of a p-type semiconductor material. The first organic semiconductor film 27 shown in FIG. 24 is located on one (−X side) of the sides of the predetermined region 23 in the first direction. The first organic semiconductor film 27 projects from the first electrode 26 to a central portion of the predetermined region 23 and continues to the upper surface of the gate insulating film 25 outside the first electrode 26. The second organic semiconductor film 28 shown in FIG. 25 is located on the other side (+X side) of the predetermined region 23 in the first direction. The second organic semiconductor film 28 projects from the first electrode 26 to a central portion of the predetermined region 23 and continues to the top of the gate insulating film 25 outside the first electrode 26. The first organic semiconductor film 27 and the second organic semiconductor film 28 are provided without being in contact with each other. The first organic semiconductor film 27 according to this embodiment has a portion projecting toward the second organic semiconductor film 28.

As shown in FIGS. 19 and 20, the second electrode 29 of the first organic thin-film transistor TR5 is provided on the first organic semiconductor film 27 to as to be in contact with the first organic semiconductor film 27. That is, a portion of the first organic semiconductor film 27 is sandwiched between the first electrode 26 and the second electrode 29 in the lamination direction of the first laminate 31. The second electrode 29 is provided over a region where the second electrode 29 overlaps the first electrode 26 in the laminate direction of the first laminate 31 and a portion of the first organic semiconductor film 27, which projects outward from the first electrode 26. In this embodiment, the second electrode 29 is formed in substantially the same planar region as the first organic semiconductor film 27. In this embodiment, the area of contact between the first organic semiconductor film 27 and the second electrode 29 is larger than that between the first organic semiconductor film 27 and the first electrode 26. Therefore, the area of the second electrode 29 is larger than the area of a region where the first electrode 26 and the third electrode 30 overlap each other in the lamination direction, i.e., the area of a portion substantially functioning as a first electrode for the first organic semiconductor film 27.

The second wiring portion 34 is electrically connected to the second electrode 29. In this embodiment, the second electrode 29 and the second wiring portion 34 are integrally formed using the same forming material. A second conductive film constituting the second electrode 29 and the second wiring portion 34 is provided to extend to the outside of the gate electrode 22 through the notch portion 24. The second conductive film extends to the notch portion 24 from the upper surface of a portion of the first organic semiconductor film 27 which projects toward the second organic semiconductor film 28.

As shown in FIGS. 19 and 20, the third electrode 30 of the second organic thin-film transistor TR6 is provided on the second organic semiconductor film 28 so as to be in contact with the second organic semiconductor film 28. That is, a portion of the second organic semiconductor film 28 is sandwiched between the first electrode 26 and the third electrode 30 in the lamination direction of the second laminate 32. The third electrode 30 is provided over a region where the third electrode 30 overlaps the first electrode 26 in the laminate direction of the second laminate 32 and a portion of the second organic semiconductor film 28 which projects outward from the first electrode 26. In this embodiment, the third electrode 30 is formed in substantially the same planar region as the second organic semiconductor film 28. In this embodiment, the area of contact between the second organic semiconductor film 28 and the third electrode 30 is larger than that between the second organic semiconductor film 28 and the first electrode 26. Therefore, the area of the third electrode 30 is larger than the area of an overlap region between the first electrode 26 and the second electrode 29 in the lamination direction, i.e., the area of a portion of the first electrode 26 substantially functioning as a first electrode for the second organic semiconductor film 28.

The third wiring portion 35 is electrically connected to the third electrode 30. In this embodiment, the third electrode 30 and the third wiring portion 35 are integrally formed using the same forming material. A third conductive film constituting the third electrode 30 and the third wiring portion 35 is provided to extend to the outside of the gate electrode 22 through the notch portion 24.

Next, an example of a method for manufacturing the organic semiconductor device according to the third embodiment is described, but the application scope of the embodiment is not limited to the manufacturing method described below.

As shown in FIG. 22, in this example, the gate electrode 22 is formed on the insulating substrate 21. The gate electrode 22 of this example is formed by forming a film having a thickness of about 300 nm by a sputtering method using as a target an alloy containing 99% by weight of aluminum and 1% by weight of silicon, and then patterning the film by a photolithography method and an etching method. Patterning is performed so that the gate electrode 22 surrounds the predetermined region 23 where the first laminate 31 and the second laminate 32 are formed except a region adjacent to the notch portion 24.

Next, as shown in FIG. 23, the gate insulating film 25 is formed to cover the gate electrode 22. The gate insulating film 25 can be formed by, for example, a sputtering method in the same manner as in the first embodiment. The gate insulating film 25 is composed of, for example, silicon oxide, and has a thickness of about 100 nm. Then, the first conductive film constituting the first electrode 26 and the first wiring portion 33 is formed on the gate insulating film 25. The first electrode 26 can be formed by, for example, a mask vacuum deposition method in the same manner as in the first embodiment. In this example, under a condition in which a metal mask having an aperture with a shape corresponding to the first electrode 26 plus the first wiring portion 33 is aligned with the insulating substrate 21, chromium is deposited to a thickness of 2 nm and then gold is deposited to a thickness of 80 nm through the metal mask to form the first conductive film having a chromium-gold two-layer structure.

Next, as shown in FIG. 24, the first organic semiconductor film 27 is formed over the first electrode 26 and a portion of the gate insulating film 25, which is positioned outside the first electrode 26 within the predetermined region 23. In this example, the first organic semiconductor film 27 is formed by depositing pentacene as a p-type organic semiconductor material to a thickness of about 60 nm through a metal mask.

Next, as shown in FIG. 25, the second organic semiconductor film 28 is formed over the first electrode 26 and a portion of the gate insulating film 25, which is positioned outside the first electrode 26 within the predetermined region 23. In this example, the second organic semiconductor film 28 is formed by depositing fullerene as a n-type organic semiconductor material to a thickness of about 60 nm through a metal mask.

Next, as shown in FIG. 26, the second electrode 29 is formed on the first organic semiconductor film 27, and the third electrode 30 is formed on the second organic semiconductor film 28. In this example, the second conductive film constituting the second electrode 29 and the second wiring portion 34 and the third conductive film constituting the third electrode 30 and the third wiring portion 35 are formed at a time. Specifically, under a condition in which a metal mask having an aperture with the same shape as the second conductive film and an aperture with the same shape as the third conductive film is aligned with the insulating substrate 21, gold is deposited to a thickness of about 80 nm through the metal mask to form the second conductive film and the third conductive film composed of gold.

As described above, the first organic thin-film transistor TR5 and the second organic thin-film transistor TR6 of the third embodiment are formed, thereby manufacturing the organic semiconductor device SD5 provided with these organic thin-film transistors. As described in the first embodiment, the organic semiconductor device SD5 of the third embodiment is capable of increasing a drain current, decreasing a parasitic capacitance and leakage current, and suppressing the occurrence of wiring disconnection due to a step difference.

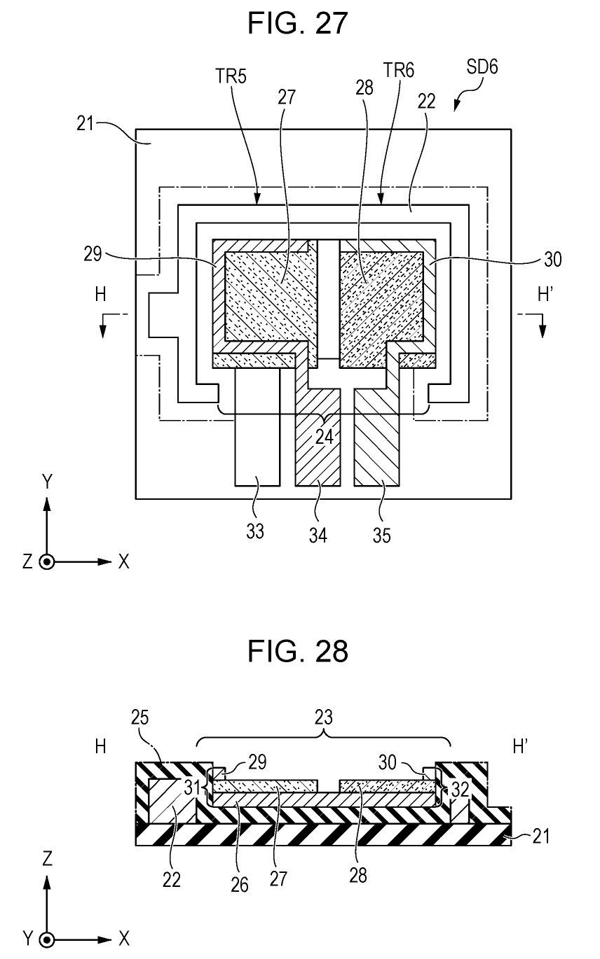

Next, the modified example 4 is described. FIG. 27 is a plan view of an organic semiconductor device according to the modified example 4. FIG. 28 is a cross-sectional view take along line H-H′ in FIG. 27. An organic semiconductor device SD6 shown in FIGS. 27 and 28 includes a first organic thin-film transistor TR5 and a second organic thin-film transistor TR6.

In the modified example 4, a first electrode 26 is formed over substantially the entire region of a predetermined region 23. A first organic semiconductor film 27 is located on one (−X side) of the sides in a direction (X direction) in which the first organic thin-film transistor TR5 and the second organic thin-film transistor TR6 are arranged. A second organic semiconductor film 28 is located on the other side (+X side) in the X direction. The second organic semiconductor film 28 is provided symmetrically with the first organic semiconductor film 27 with respect to a phantom line perpendicular the X direction.

A second electrode 29 included in a first laminate 31 of the first organic thin-film transistor TR5 is partially provided on the first organic semiconductor film 27. In this example, the second electrode 29 has a substantially C-shaped strip form. The second electrode 29 is provided inside a gate electrode 22 at a predetermined distance corresponding to the thickness of a gate insulating film 25 and extends to be bent along the gate electrode 22. The area of a portion where the first organic semiconductor film 27 and the second electrode 29 overlap each other in the lamination direction of the first laminate 31 is smaller than the area of a portion where the first electrode 26 and the first organic semiconductor film 27 overlap each other in the lamination direction. That is, in the first laminate 31, when focusing attention on a portion substantially functioning as an electrode for the first organic semiconductor film 27, the area of the first electrode 26 is larger than the area of the second electrode 29.

A third electrode 30 included in a second laminate 32 of the second organic thin-film transistor TR6 is partially provided on the second organic semiconductor film 28. In this example, the third electrode 30 has a substantially C-shaped strip form symmetrical with the second electrode 29 of the first organic thin-film transistor TR5. The third electrode 30 is apart at a predetermined distance corresponding to the thickness of the gate insulating film 25 from the inside of a gate electrode 22 and extends to be bent along the gate electrode 22. The area of a portion where the second organic semiconductor film 28 and the third electrode 30 overlap each other in the lamination direction of the second laminate 32 is smaller than the area of a portion where the first electrode 26 and the second organic semiconductor film 28 overlap each other in the lamination direction. That is, in the second laminate 32, when focusing attention on a portion substantially functioning as an electrode for the second organic semiconductor film 28, the area of the first electrode 26 is larger than the area of the third electrode 30.

In the modified example 4, in the first organic thin-film transistor TR5, the area of a portion of the first electrode 26 substantially functioning as an electrode is different from the area of a portion of the second electrode 29 substantially functioning as an electrode. Therefore, the first organic thin-film transistor TR5 is capable of decreasing a leakage current and parasitic capacitance. For the same reason, the second organic thin-film transistor TR6 is capable of decreasing a leakage current and parasitic capacitance.

### Fourth Embodiment

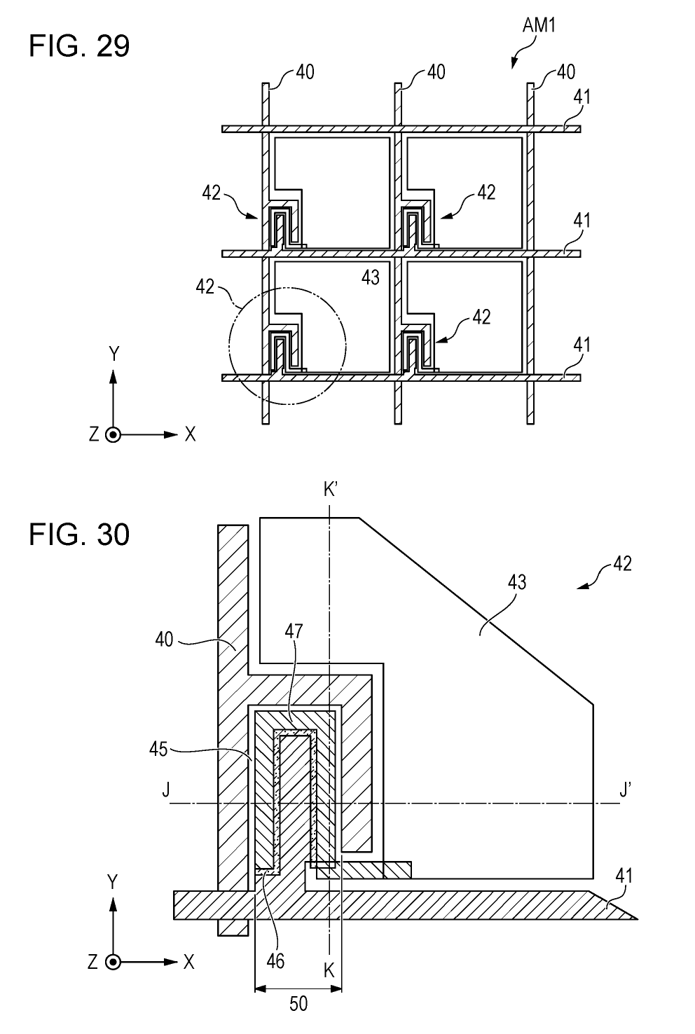

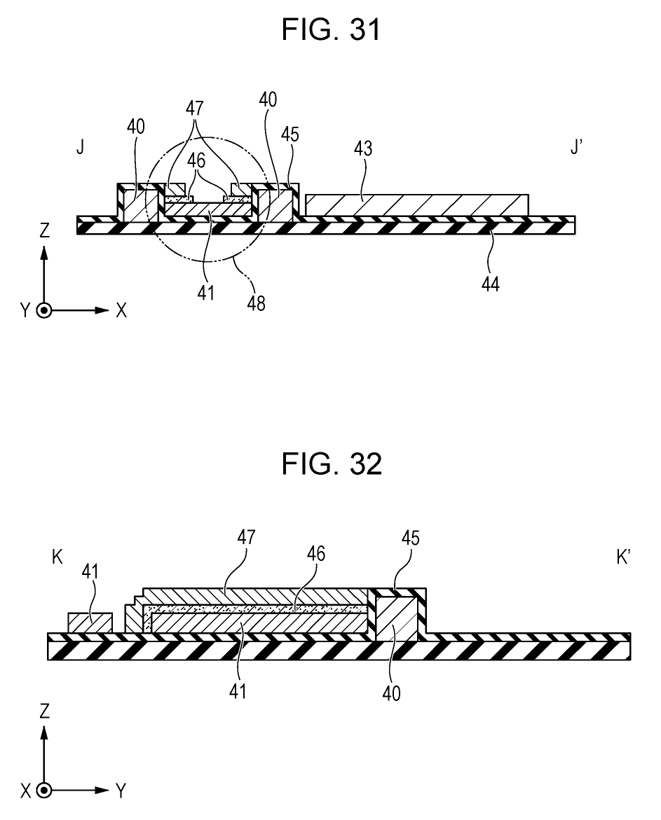

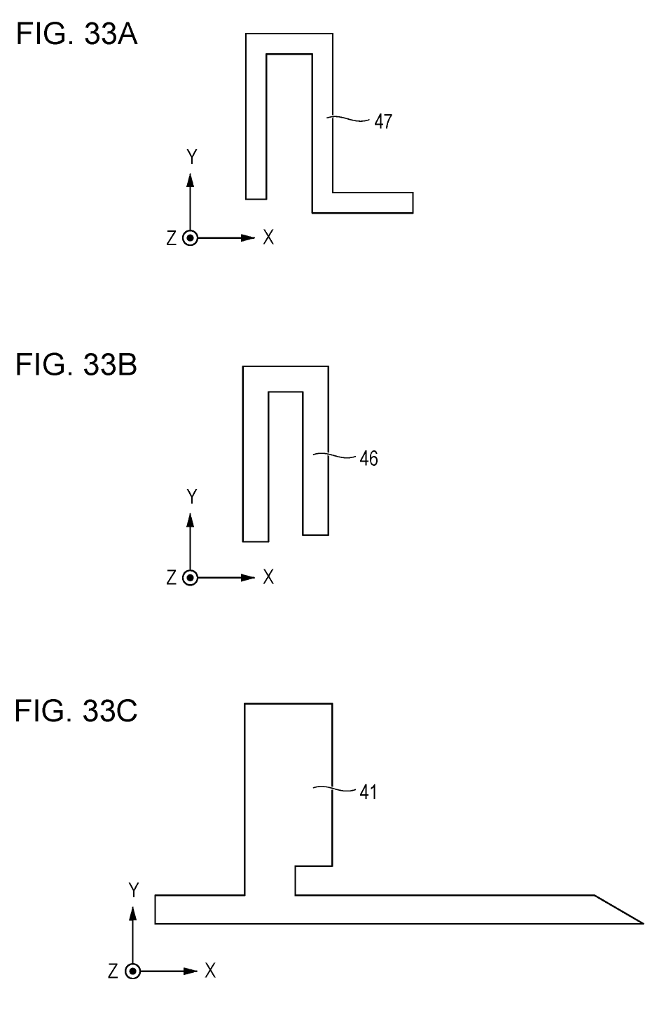

Next, a fourth embodiment is described. FIG. 29 is a plan view of an organic semiconductor device array according to the fourth embodiment. FIG. 30 is a plan view of an organic semiconductor device according to the fourth embodiment. FIG. 31 is a cross-sectional view take along line J-J′ in FIG. 30. FIG. 32 is a cross-sectional view take along line K-K′ in FIG. 30. FIGS. 33A to 33C are plan views of respective constituent elements of the organic semiconductor device according to the fourth embodiment.

An organic semiconductor device array AM1 shown in FIG. 29 includes a plurality of organic semiconductor devices 42 arranged in a matrix pattern. Each of the organic semiconductor devices 42 is composed of the organic semiconductor device of any one of the above-described embodiments and modified examples. The organic semiconductor device array AM1 can be employed in, for example, a liquid crystal display device, an organic electroluminescence display device, and the like.

The organic semiconductor device array AM1 includes a plurality of gate wirings 40, a plurality of source wirings 41, and a plurality of pixel electrodes 43. The plurality of gate wirings 40 have portions extending in parallel to each other. The plurality of source wirings 41 have portions perpendicular to the gate wirings 40 and extending in parallel to each other. The pixel electrodes 43 are provided in one-to-one correspondence with regions (hereinafter referred to as “pixel regions”) partitioned by the source wirings 40 and the source wirings 41. The organic semiconductor devices 42 are disposed at the intersections between the gate wirings 40 and the source wirings 41. The organic semiconductor devices 42 are provided in one-to-one correspondence with the pixel electrodes 43. A plurality of the organic semiconductor devices 42 arranged in the extension direction (the Y direction in the drawing) of the gate wirings 40 are connected to the same gate wiring 40. A plurality of the organic semiconductor devices 42 arranged in the extension direction (the X direction in the drawing) of the source wirings 41 are connected to the same source wiring 41.

Each of the organic semiconductor devices 42 includes the gate wiring 40 functioning as a gate electrode, a gate insulating film 45, and a laminate 48. The laminate 48 includes the source wiring 41 functioning as a first electrode, an organic semiconductor film 46, and a drain electrode 47 functioning as a second electrode. The laminate 48 is disposed near the intersection between the gate wiring 40 and the source wiring 41. The gate wiring 40 has a branch portion disposed near the intersection between the gate wiring 40 and the source wiring 41. The branch portion extends to be bent along the periphery of the laminate 48 excluding between the laminate 48 and the source wiring 41 adjacent to the laminate 48. The gate insulating film 45 is provided at least between the laminate 48 and the gate wiring 40 adjacent to the laminate 48. In this embodiment, the gate insulating film 45 is provided over substantially the entire region of the upper surface of an insulating substrate 44 to cover the gate wiring 40. The laminate 48 and the source wiring 41 are provided on the gate insulating film 45.

As shown in FIGS. 30 and 33C, the source wiring 41 has a branch portion disposed near the intersection between the source wiring 41 and the gate wiring 40. The branch portion functions as the first electrode of the organic semiconductor device 42. As shown in FIG. 33B, the organic semiconductor film 46 is provided in a substantially U-shaped strip form along the periphery of the branch portion of the source wiring 41. That is, the top of the branch portion of the source wiring 41 includes a region where the organic semiconductor film 46 is not formed. As shown in FIG. 33A, the drain electrode 47 is formed to fit on the organic semiconductor film 46. The drain electrode 47 is electrically connected to the pixel electrode 43.

In this embodiment, the area of a portion where the branch portion (first electrode) of the source wiring 41 and the drain electrode 47 overlap each other in the lamination direction of the laminate 48 is smaller than the area of the first electrode. The area of contact between the drain electrode (second electrode) 47 and the organic semiconductor film 46 is smaller than the area of contact between the branch portion (first electrode) of the source wiring 41 and the organic semiconductor film 46.

In the organic semiconductor device array AM1 of this embodiment, a driving circuit (driver) (not shown) line-sequentially applies a gate voltage to the plurality of gate wirings 40. As a result, the plurality of organic semiconductor devices 42 arranged along the gate wiring 40 to which the gate voltage is applied are turned on. With the organic semiconductor device 42 turned on, a signal (voltage) waveform supplied to the source wiring 41 is inputted to the pixel electrodes 43 through the organic semiconductor films 46 and the drain electrodes 47. The signal waveform inputted to the pixel electrodes 43 is used for displaying an image or the like.

The organic semiconductor device array AM1 of the fourth embodiment includes the organic semiconductor devices of any one of the above-described embodiments or modified examples and is thus capable of increasing a drain current, improving yield, and decreasing a leakage current and parasitic capacitance. In addition, the organic semiconductor device array AM1 of the fourth embodiment is capable of decreasing the area of the organic semiconductor device array AM1 in each pixel as compared with the use of a planar-type structure exhibiting the same performance. Thus, for example, when the organic semiconductor device array AM1 is applied to a display device, an effective area of pixels contributing to display, i.e., an aperture ratio, can be improved.

### Fifth Embodiment

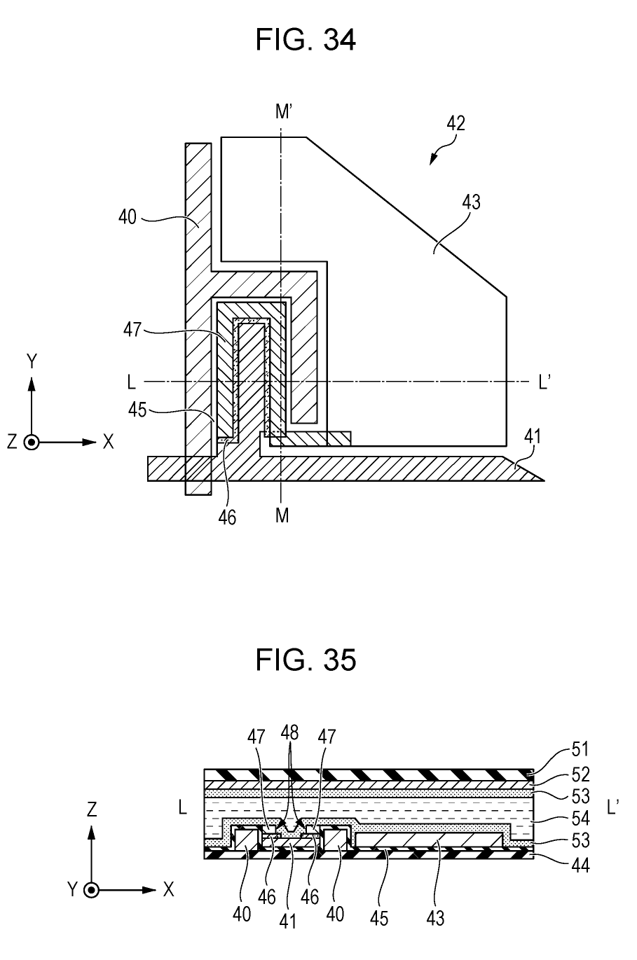

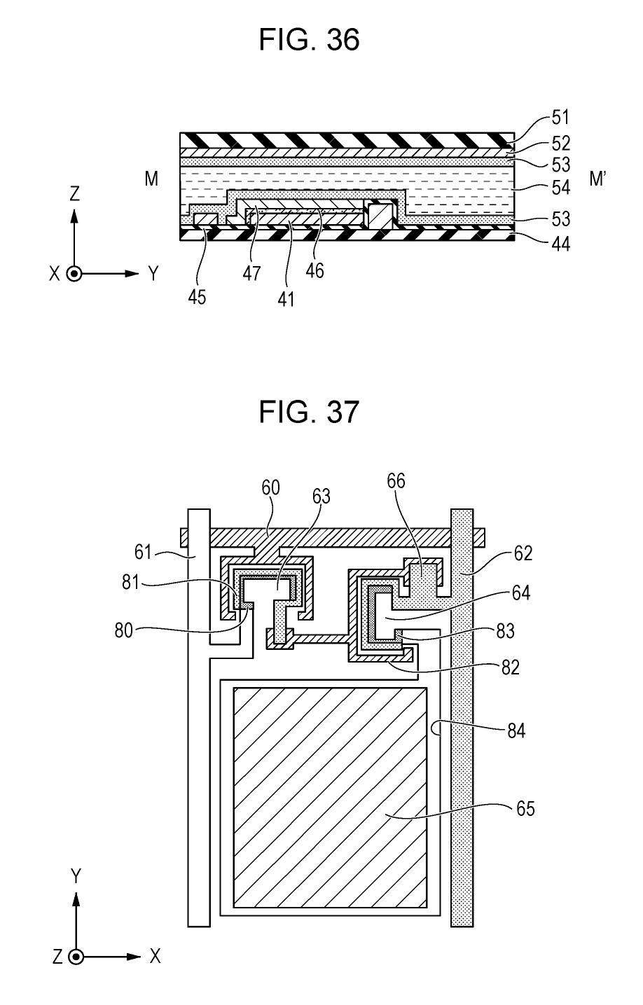

Next, a fifth embodiment is described. FIG. 34 is a plan view of an organic semiconductor device in an organic semiconductor device array of a liquid crystal display device according to the fifth embodiment. FIG. 35 is a cross-sectional view take along line L-L′ in FIG. 34. FIG. 36 is a cross-sectional view take along line M-M′ in FIG. 34.

The liquid crystal display device of this embodiment includes the organic semiconductor device array AM1 described in the fourth embodiment, a counter substrate 51, a counter electrode 52, an alignment film 53, and a liquid crystal layer 54. The counter substrate 51 is disposed opposite to the insulating substrate 44. The insulating substrate 44 and the counter substrate 51 are bonded together with resin beads or the like (not shown) provided therebetween for maintaining a cell gap corresponding to the thickness of the liquid crystal layer 54. The counter substrate 51 is a transparent substrate appropriately selected from the substrates which can be used as the insulating substrate described in the first embodiment.

The liquid crystal layer 54 is sealed between the insulating substrate 44 and the counter substrate 51. The counter electrode 52 is disposed between the counter substrate 51 and the liquid crystal layer 54. The counter electrode 52 can apply an electric field to the liquid crystal layer 54 between the counter electrode 52 and the pixel electrodes 43. The alignment film 53 is disposed each of between the liquid crystal layer 54 and the counter substrate 51 and between the liquid crystal layer 54 and the pixel electrodes 43. The alignment film 53 can align the liquid crystal layer 54. The alignment film 53 between the liquid crystal layer 54 and the pixel electrodes 43 is provided to cover the pixel electrodes 43 and the organic thin film transistors.

The liquid crystal display device of this embodiment uses, as a substrate for active matrix drive, an organic semiconductor device array including the organic semiconductor devices of any one of the above-described embodiments and modified examples. Therefore, it is possible to improve an aperture ratio of pixels and realize a high-quality display. Since the organic thin-film transistor of this embodiment has decreased parasitic capacitance, thereby suppressing delay due to the parasitic capacitance when data is written on each pixel. Therefore, for example, when the number of pixels in the liquid crystal display device is increased or the screen is enlarged, display timing lag in the pixels in each frame is decreased, and thus a high-quality display can be realized. Also, the liquid crystal display device of this embodiment causes little defect such as wiring disconnection due to step differences in the organic thin-film transistors, and thus the yield can be improved.

### Sixth Embodiment

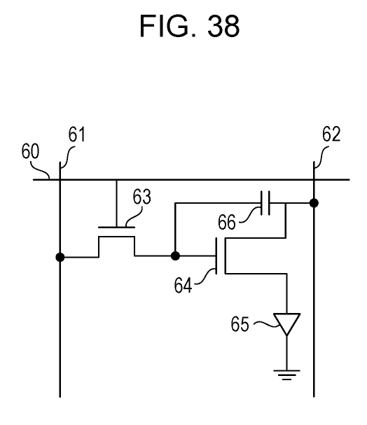

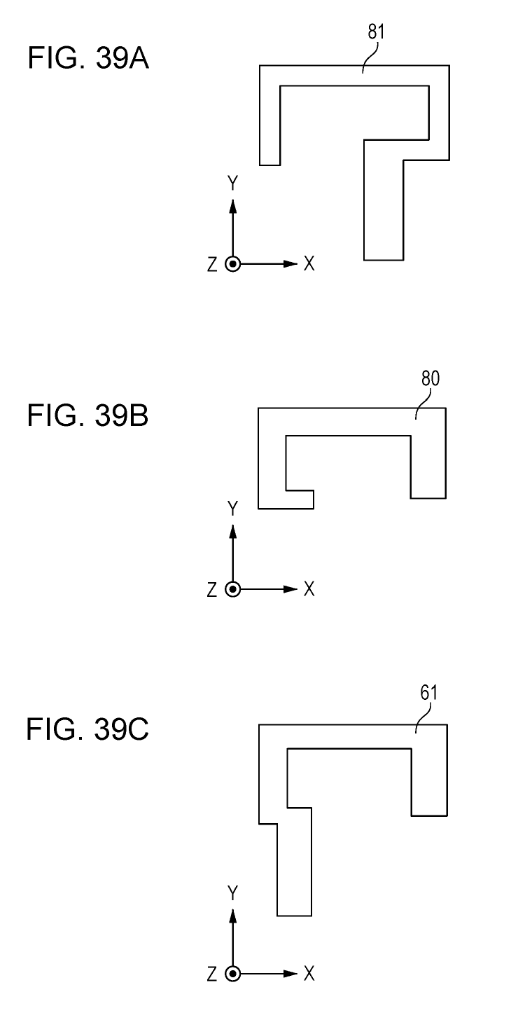

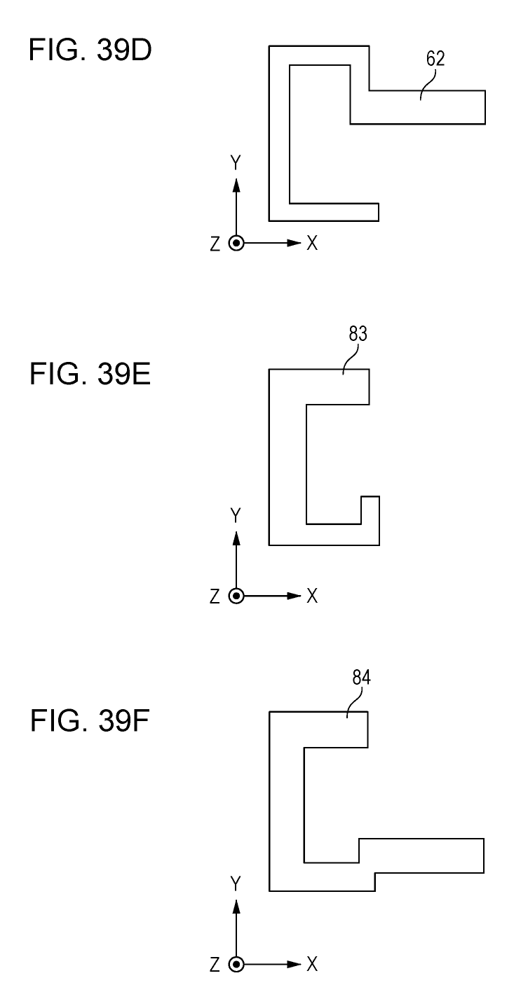

Next, a sixth embodiment is described. FIG. 37 is a plan view of an organic semiconductor device in an organic semiconductor device array of an organic electroluminescence display device according to the sixth embodiment. FIG. 38 is an equivalent circuit diagram of the organic semiconductor device according to the sixth embodiment. FIGS. 39A to 39F are plan views of respective constituent elements of the organic semiconductor device according to the sixth embodiment.

The organic electroluminescence display device (hereinafter referred to as the “organic EL display device”) according to the sixth embodiment has a so-called 2T1C-type (2-transistor-1-capacitor) structure. The organic EL device of this embodiment has many pixels arranged in a two-dimensional form. FIG. 37 shows a portion corresponding to one pixel.

The organic EL display device shown in FIG. 37 includes a gate line 60, a signal line 61, a power supply line 62, a switching transistor 63, a driving transistor 64, an organic EL element 65, and a capacitor 66. The signal line 61 and the power supply line 62 have portions extending in parallel to each other. The gate line 60 has a portion extending in parallel to the signal line 61 and the power supply line 62. The gate line 60 can transmit a signal for selecting a pixel. The signal line 61 can transmit a signal indicating image data. The power supply line 62 can supply electric power to emit light from the organic EL element 65.

The organic EL element 65 has a structure in which an organic light-emitting layer is disposed between a pair of electrodes. The organic EL element 65 can emit light from the light-emitting layer by energy of bonding of carriers (holes and electrons) supplied from the pair of electrodes. The switching transistor 63 can control on-off of the driving transistor 64 based on a signal transmitted from the gate line 60. The driving transistor 64 can switch the supply of electric power from the power supply line 62 to the organic EL element 65. The capacitor 66 can maintain the signal supplied to the organic EL element 65.

The switching transistor 63 has a laminate including a first electrode branched from the signal line 61 shown in FIG. 39C, an organic semiconductor film 80 shown in FIG. 39B, and a second electrode 81 shown in FIG. 39A, which are laminated with each other. The laminate of the switching transistor 63 is disposed near the intersection between the gate line 60 and the signal line 61. The gate line 60 has a branch portion disposed near the intersection between the gate line 60 and the signal line 61. The branch portion of the gate line 60 surrounds the periphery of the laminate of the switching transistor 63 excluding a portion of the periphery.

The driving transistor 64 has a laminate including a first electrode branched from the power supply line 62 shown in FIG. 39D, an organic semiconductor film 83 shown in FIG. 39E, and a second electrode 81 shown in FIG. 39F, which are laminated with each other. The laminate of the driving transistor 64 is disposed near the intersection between the gate line 60 and the power supply line 62. The second electrode 81 of the switching transistor 63 surrounds the periphery of the laminate of the driving transistor 64 excluding a portion of the periphery of the laminate. A portion of the second electrode 81 of the switching transistor 63 faces the branch portion branched from the power supply line 62 with a capacitor insulating film (not shown) disposed therebetween. The second electrode 84 of the driving transistor 64 is electrically connected to one (pixel electrode) of the pair of electrodes of the organic EL element 65.

The organic EL display device of this embodiment includes the organic semiconductor device having the organic thin-film transistor of any one of the above-described embodiments and modified examples. Therefore, the organic EL display device of this embodiment can increase a drain current without decreasing a pixel aperture ratio as compared with the use of a thin-film transistor having a planar-type structure. Thus, the organic EL display device of this embodiment is capable of sufficiently supplying electric power necessary for emitting light to the organic EL element 65, thereby achieving a high-luminance display. The organic EL display device of this embodiment causes little defect such as wiring disconnection due to a step difference in the organic thin-film transistor, thereby improving the yield.

### INDUSTRIAL APPLICABILITY

An organic semiconductor device according to the present invention can be used in an image display device, an electronic device such as a RFID tag, and the like, which include organic thin-film transistors.

### REFERENCE SIGNS LIST

1, 21 insulating substrate (substrate)
2, 25 gate electrode
3, 23 predetermined region (first region)
4, 24 notch portion (second region)
5, 25 gate insulating film
6, 26 first electrode
7 organic semiconductor film
8, 29 second electrode
9 laminate
11 first wiring portion
12 second wiring portion
27 first organic semiconductor film
28 second organic semiconductor film
30 third electrode
35 third wiring portion
SD1 to SD5 organic semiconductor device
TR1 to TR5 organic thin-film transistor

1. An organic semiconductor device comprising:
a laminate provided in a first region of a substrate and including a first electrode, a first organic semiconductor film, and a second electrode which are laminated with each other, the first organic semiconductor film being placed between the first electrode and the second electrode;
a first wiring portion provided in a second region adjacent to a portion of the periphery of the first region so as to be electrically connected to the first electrode;
a second wiring portion provided in the second region so as to be electrically connected to the second electrode;
a gate electrode provided to surround a portion of the periphery of the first region; and
a gate insulating film provided at least between the laminate and the gate electrode,
wherein the first region has a substantially rectangular shape; and
the gate electrode is provided to surround three sides of the first region and surround a portion of one side except the three sides of the first region.

2. The organic semiconductor device according to claim 1, wherein the area of the first electrode is different from the area of the second electrode.

3. The organic semiconductor device according to claim 1, wherein the area of a portion where the first organic semiconductor film and the first electrode overlap each other in the lamination direction of the laminate is different from the area of a portion where the first organic semiconductor film and the second electrode overlap each other in the lamination direction of the laminate.

4. The organic semiconductor device according to claim 1, wherein the first organic semiconductor film is made of an n-type semiconductor material or a p-type semiconductor material.

5. The organic semiconductor device according to claim 1, comprising:
the first organic semiconductor film partially covering the first electrode, and the second electrode formed on the first organic semiconductor film;
a second organic semiconductor film provided on the first electrode within a region different from the first organic semiconductor film;
a third electrode provided on the second organic semiconductor film; and
a third wiring portion provided in the second region so as to be electrically connected to the third electrode,
wherein one of the first organic semiconductor film and the second organic semiconductor film is made of an n-type semiconductor material, and the other is made of a p-type semiconductor material.

6. The organic semiconductor device according to claim 1,
wherein the first organic semiconductor film contains a plurality of organic molecules which are chemically bonded to each other; and
the molecular axes of the plurality of organic molecules are aligned to develop π-conjugation of the plurality of organic molecules in a direction connecting the first electrode and the second electrode.

7. (canceled)

8. An organic semiconductor device array comprising an array of a plurality of the organic semiconductor devices according to claim 1.

9. A liquid crystal display device comprising at least one of the organic semiconductor device according to claim 1.

10. An organic electroluminescence display device comprising at least one of the organic semiconductor device according to claim 1.

11. A liquid crystal display device comprising the organic semiconductor device array according to claim 8.

12. An organic electroluminescence display device comprising the organic semiconductor device array according to claim 8.
